(19) United States
(12) Patent Application Publication
(10) Pub. No.: US 2016/0079461 A1
(43) Pub. Date: Mar. 17, 2016

(54) SOLAR GENERATOR WITH FOCUSING OPTICS INCLUDING TOROIDAL ARC LENSES

(71) Applicant: The Arizona Board of Regents on Behalf of the University of Arizona, Tucson, AZ (US)

(72) Inventors: Roger P. Angel, Tucson, AZ (US); Brian M. Wheelwright, Tucson, AZ (US)

(21) Appl. No.: 14/632,637

(22) Filed: Feb. 26, 2015

Related U.S. Application Data
(60) Provisional application No. 61/945,721, filed on Feb. 27, 2014.

(51) Int. Cl. H01L 31/054; H01L 31/0725; H01L 31/05; H01L 31/0687

(52) U.S. Cl. CPC H01L 31/0547; H01L 31/0543; H01L 31/0687; H01L 31/0725; H01L 31/0504

(57) ABSTRACT

We disclose here a new type of solar generator using an optical concentrator in which sunlight is concentrated successively in each of two dimensions. Sunlight is first reflected toward a linear focus by a large, deeply-curved, cylindrical trough reflector of parabolic shape. Before the reflected light comes to the focus, it passes through smaller, regularly spaced toroidal arc lenses which further concentrate it in the orthogonal direction. The lenses have the two-dimensional cross section of a convex lens, extended into a toroid by rotation about an axis parallel to the line focus. The toroidal arc lenses operate to efficiently focus at very high-concentration converging rays that are incident from a wide range of directions, from the deeply curved primary reflector. The foci formed by the toroidal arc lenses are formed at regular intervals, spaced along a line parallel to and close to the primary linear trough focus. The concentrated sunlight at these foci is converted into electricity preferably by multi junction photovoltaic cells of very high efficiency, configured in short, parallel-connected linear arrays. In one embodiment, tolerance to off-axis pointing and uniformity of illumination is improved with an additional refractive element in the form of a rod lens, introduced close to and parallel to each cell array, so as to image the outline of the toroidal arc lenses onto the cells.

### CROSS-REFERENCE TO RELATED APPLICATIONS

This application is based upon and claims the benefit of the filing date of provisional patent application Ser. No. 61/945,721, filed Feb. 27, 2014, entitled “Solar Generator With Focusing Optics Including Toroidal Arc Lenses,” the entire disclosure of which is incorporated herein by reference.

### BACKGROUND

The present invention relates to the generation of electrical power using optically concentrated sunlight. In the most widely used systems of this type, cylindrically curved parabolic trough mirrors are used to concentrate sunlight in one dimension to heat a thermal transfer fluid. The mirrors are turned about a single North-South axis to track the sun. Electricity is made with a conventional steam turbine generator from thermal energy gathered at the line focus. The reflectors for these systems are made inexpensively by cylindrically bending sheets of reflective material or of hot glass which is subsequently back silvered. However, the electricity made by such systems is expensive, because of the low conversion efficiency of this type of thermal generation. Typically only 15% of the incident solar power is converted into electrical power. Also, these installations are necessarily extremely large and require very large capital investment. The cost of daytime electricity made by such systems is not competitive in cost with that made using flat PV panels or made conventionally from fossil fuels.

In another type of solar generation, concentrating photovoltaics (CPV), sunlight is focused onto photovoltaic cells for direct conversion into electricity. Very high efficiency may be achieved through use of multi junction PV cells which convert sunlight into electricity with twice the efficiency of flat silicon PV panels. But multi junction cells are much more expensive per unit area than PV panels, so in order to make such generation economical, the cells must be of small area and be operated under highly concentrated sunlight.

A number of approaches have been described for achieving the required high solar concentration onto PV cells. Most use primary optics that concentrate sunlight symmetrically to a point focus, i.e. equally in both dimensions. Examples of such 2-D concentrating elements are Fresnel lenses and dish-shaped or paraboloidal reflectors.

An alternative method that has been described performs the optical concentration in two successive stages, with a cylindrical primary reflector first directing the sunlight toward a line focus, where a line of secondary optical elements further concentrate the light in the orthogonal direction.

In one of these methods, shown in Brunotte, Goetzberger & Blieske, “Two-Stage Concentrator Permitting Concentration Factors Up To 300× With One-Axis Tracking,” Solar Energy, Vol. 56, No. 3, pp. 285-300 (1996), the line focus of a cylindrical parabolic trough reflector is arrayed with reflective, asymmetric compound parabolic concentrators (CPCs). The low concentration line focus is broken up into regions of modestly higher concentration at the output aperture of the CPCs. CPCs are designed to have a sharp cutoff in acceptance angle. When the trough is tracked about a polar axis, the CPCs must accept and concentrate all light with an azimuthal incidence angle between −23.5° and +23.5°.

Another CPC-based approach described in Cooper, Ambrosetti, Pedretti & Steinfeld, “Theory And Design Of Line-To-Point Focus Solar Concentrators With Tracking Secondary Optics,” Applied Optics, Vol. 52, No. 35, pp. 8586-8616 (2013), tracks the parabolic trough about a horizontal North-South axis. The large range of incidence angles (greater than the CPC acceptance angle) is accommodated by the addition of a pivoting reflector to redirect sunlight into the CPC aperture. Each CPC/cell assembly includes its own pivoting CPC assembly.

In another orthogonal focusing concept, a parabolic trough of long focal ratio, tracked along either a N-S horizontal or polar axis, is used with an array of conventional cylindrical or spherical lenses near the line focus, as disclosed in U.S. Patent Application Publication No. US 2011/0023866 A1, for “Solar Receiver For A Solar Concentrator With A Linear Focus,” to Balbo di Vinadio & Palazzetti (Feb. 3, 2011). See also EP 2,280,421, to Balbo di Vinadio & Palazzetti, and International Publication No. WO 2005/116534 A2, to Williams and Pizzoli, for similar disclosures. The result is to reformat the continuous linear focus of the trough into a series of short, perpendicular, and more intense linear foci, separated by the same interval as the lenses. Solar cells are arranged in strips at these foci. Sun-tracking is performed by shifting the optics array relative to the cells in a direction parallel to the original line focus. Or, the trough may be tracked in two dimensions while the relative lens and cell positions remain fixed

Costs for concentrating optics built according to the prior art have so far remained high and left these concentrating PV systems non-competitive with flat PV panels used without concentration. A particular difficulty with the orthogonal focusing methods described to date is that the degree of concentration and ability to track the sun through the year are limited by tracking errors and by optical aberrations. Thus in the prior art, to control aberrations the primary mirror (line-focus parabolic trough) must subtend a small angle as viewed by the secondary optics, which cannot accept wide, rapidly converging ray bundles. When the secondary lens array is comprised of conventional cylindrical or spherical lenses, the primary reflector must be optically slow (high F/#). Otherwise, sunlight incident on the outer edges of the primary mirror is not properly brought to a focus at the strip-shaped cell target. Long focal ratio leads to low concentration by the primary reflector, large moving structures, and high cost. Further driving cost is the need for these structures to be accurately oriented, because the orthogonal focusing concentrating systems in prior art are not optically stabilized against mispointing. Under ideal operation, the optical system is maintained in perfect alignment with the sun. However, in practice the tracking is not perfect, so the highly elliptical sun image drifts over the cell plane. A further limitation of current orthogonal concentrating systems is that they suffer from optical aberrations that prevent high concentration for the primary reflector, and hence for the optical system as a whole. Aberrations are especially problematic for the case where the primary paraboloidal reflector is simply mounted to turn about a horizontal N-S axis. Because of these deficiencies, the very high concentration needed to make triple junction cell systems cheaper than flat PV panel systems is not realized by current state of the art.

### SUMMARY

The present invention is for high concentration, orthogonal focusing optics which overcome the limitations of prior art. The first element is a cylindrically curved parabolic trough reflector of very short focal ratio, for example F/0.5 or faster. There are two strong reasons for this choice of first element: very short focal ratio greatly facilitates very high concentration—concentration of ˜50× is achieved by the primary reflector alone at the intermediate line focus of an F/0.5 parabola; second, primary reflectors of exactly this type are inexpensive because they are simple to manufacture by bending of flat reflective material. Manufacture of back-silvered glass reflectors of this type in very high volume and at low cost has been demonstrated by the solar industry for thermal solar plants.

The key innovation of this invention is the design of the secondary concentrating element, taking the form of a “toroidal arc lens” array. This element, when illuminated by the primary concentrating element in the form of a parabolic trough mirror of short focal ratio, realizes optical concentration up to 1000×. The light reflected by the primary trough element is intercepted by the regularly spaced “toroidal arc” lenses before it come to a focus. The toroidal arc lenses further concentrate the light in the orthogonal direction. A toroidal arc lens has the cross section in two-dimensions of a convex lens, and extends into the third dimension by rotation in an arc around a line parallel to the primary (˜50×) line focus. It operates to efficiently focus at very high-concentration rays that are incident from a wide range of directions, as from a deeply curved primary reflector. The cross-line foci formed by the toroidal arc lenses are formed at regular intervals spaced along a line parallel to and close to the primary linear trough focus. In this way, the toroidal arc lens array can realize a further 10×-20× concentration, for an overall system concentration of up to 1000×.

To increase tolerance to off-axis pointing and improve uniformity of illumination of the cells, in one embodiment an additional refractive element in the form of a rod lens is introduced close to and parallel to each cell array, so as to image in one dimension the outline of the secondary optics onto the cells. In this way, tracking errors in one dimension are substantially stabilized optically, by the principle of Koehler illumination. The concentrated sunlight at the individual foci may be converted into electricity by multi junction photovoltaic cells, configured in short, parallel-connected linear arrays.

Another key innovation of this invention is a novel parabolic trough configuration, where different segments of the trough are slightly tilted or displaced laterally so as to form two or more line foci that are slightly displaced from each other. These laterally separated but parallel line foci illuminate cell cards with multiple facets. This approach allows the toroidal arc lens concentrators to function effectively with very optically fast troughs, down to F/0.25. Troughs of this focal ratio are standard in solar thermal trough systems.

Another advantage of creating multiple regions of high concentration is that passive cell cooling becomes feasible. Point-focus concentrators with large apertures usually require active coolant flow to keep the cells within operational temperatures. Point focus concentrator arrays with small individual apertures (such as Fresnel lenses) more commonly cool cells passively, since the heat dissipation is distributed spatially. The present invention allows the use of a very large aperture (parabolic trough), while still distributing the line foci along the length of receiver.

Another advantage of the present invention is the ability to maintain performance over very large incidence angle ranges. When the parabolic troughs are tracked on horizontal North-South axis, the range of incidence angles on the receiver is very large (much greater than +/−23.5 degrees), with the range increasing with latitude. In the present invention, it is demonstrated that non-linear relative motion between the toroidal arc lens array and cells can maintain concentration performance throughout the year.

### BRIEF DESCRIPTION OF THE DRAWINGS

FIG. 1A shows an F/0.5 parabolic trough, illuminated by sun rays at one end, which are focused on the toroidal arc lens array.

FIG. 1B is a detail view of the illuminated end of the toroidal arc lens array of FIG. 1A, with obstructing structural members removed.

FIG. 2 shows an F/0.5 parabolic trough tracked on a dual axis mount.

FIG. 3 shows the dual-axis tracked parabolic trough of FIG. 2 illuminated by on-axis sun rays.

FIG. 4 is an alternate view of FIG. 3, looking down the trough parallel to the overall line focus.

FIG. 5 is a side view of FIG. 3, looking perpendicular to the overall line focus and support structure.

FIG. 6 shows a dual-axis tracked parabolic trough illuminated by sun rays which are misaligned to the parabolic trough in the zenithal direction.

FIG. 7 is an alternate view of FIG. 6, looking down the trough parallel to the overall line focus.

FIG. 8 is a side view of FIG. 6, looking perpendicular to the overall line focus and support structure.

FIG. 9 shows a dual-axis tracked parabolic trough illuminated by sun rays which are misaligned to the parabolic trough in the azimuthal direction.

FIG. 10 is an alternate view of FIG. 9, looking down the trough parallel to the overall line focus.

FIG. 11 is a side view of FIG. 9, looking perpendicular to the overall line focus and support structure.

FIG. 12 shows one toroidal arc lens array embodiment which includes rod lens tertiary elements, designed for operation with F/0.5 parabolic troughs on a dual-axis tracker.

FIG. 13 is an alternate view of FIG. 12, looking down the toroidal arc lens array parallel to the overall parabolic mirror line focus.

FIG. 14 is a cross-sectional view of FIG. 13 (toroidal arc lens array), illuminated by on-axis solar rays.

FIG. 15 is a cross-sectional view of FIG. 13 (toroidal arc lens array), illuminated by off-axis solar rays which are mispointed in the zenithal direction.

FIG. 16 shows a set of 5 toroidal arc lens segments, each conjugate to a rod lens, illuminated by on-axis solar rays from a 3 m wide F/0.5 parabolic trough.

FIG. 17 is an alternate view of FIG. 16, looking parallel to the overall line focus down the length of the toroidal arc lens array.

FIG. 18 is a side view of FIG. 16, looking perpendicular to the overall line focus and support structure. The toroidal arc lens segments are shown partially transparent to reveal the underlying ray paths.

FIG. 19 is the solar irradiance distribution on the cell plane. The five toroidal arc lens segments of FIGS. 16-18 produce this pattern when illuminated by on-axis solar rays. Units are geometric concentration factor.

FIG. 20 is the solar irradiance distribution on a single cell strip of the exemplary system shown in FIGS. 16-18, illuminated by on-axis solar rays. Units are geometric concentration factor.

FIG. 21 is the same solar irradiance distribution as that shown in FIG. 20, but now represented with contours of equal concentration.

FIG. 22 shows a toroidal arc lens array (with rod lenses) looking parallel to the overall line focus down the length of the toroidal arc lens array. The lenses are illuminated with off-axis rays which are mispointed by 0.5 deg in the zenithal direction.

FIG. 23 is the solar irradiance distribution on the cell plane due to the illumination condition of FIG. 22 (0.5 deg mispointing in zenithal direction). Units are geometric concentration factor.

FIG. 24 is the solar irradiance distribution on a single cell strip of the distribution in FIG. 23. The illumination condition is 0.5 deg mispointing in the zenithal direction. Units are geometric concentration factor.

FIG. 25 is the same solar irradiance distribution as that shown in FIG. 24, but now represented with contours of equal concentration.

FIG. 26 is a side view of the optics described in FIG. 16, but with off-axis illumination (0.75 deg mispointing in the azimuthal direction). The view is looking perpendicular to the overall line focus and support structure. The toroidal arc lens segments are shown partially transparent to reveal the underlying ray paths.

FIG. 27 is the solar irradiance distribution on the cell plane of the exemplary toroidal arc lens system FIG. 26 (with 0.75 deg mispointing in the azimuthal direction). Units are geometric concentration factor.

FIG. 28 is the solar irradiance distribution on a single cell strip of the distribution shown in FIG. 27. Units are geometric concentration factor.

FIG. 29 is the same solar irradiance distribution as that shown in FIG. 28, but now represented with contours of equal concentration.

FIG. 30 shows an F/0.5 parabolic trough tracked on a single-axis which is substantially parallel to the earth's polar axis.

FIG. 31 shows the polar-axis tracked parabolic trough of FIG. 30 illuminated by on-axis sun rays.

FIG. 32 is a side view of FIG. 31, looking perpendicular to the overall line focus and support structure. Illumination is on-axis.

FIG. 33 shows an F/0.5 parabolic trough tracked on a single-axis which is substantially parallel to the earth's polar axis, illuminated by off-axis sun rays which are mispointed in the azimuthal direction. The rays represent the illumination experienced on the winter solstice.

FIG. 34 is an alternate view of FIG. 33, viewed with a line of sight perpendicular to the support structure and polar axis. The rays represent illumination experienced on the winter solstice.

FIG. 35 is a cross-sectional view of a 4-segment toroidal arc lens array without rod lenses. Illumination is on-axis.

FIG. 36 is a cross-sectional view of a 4-segment toroidal arc lens array without rod lenses. Illumination is off-axis and the cell card is translated relative to the toroidal arc lens array to maintain concentrated illumination on the cells.

FIG. 37 shows an F/0.5 parabolic trough tracked on a horizontal single-axis oriented North-South.

FIG. 38 shows the horizontally tracked parabolic trough of FIG. 37 illuminated by on-axis sun rays. This condition is met only briefly during certain parts of the year (for example, on the equinoxes at sunrise and sunset).

FIG. 39 is a side view of horizontally tracked parabolic trough with two rays sets which illustrate the seasonal extremes for a tracker located near 33 deg latitude. The seasonal extremes are winter solstice noon and summer solstice morning.

FIG. 40 is a graph of sun positions (elevation and azimuth) over the whole year at a site near 33 deg latitude, with shading indicating off-axis incidence angle on the trough.

FIG. 41 is the intensity-weighted importance of each incidence angle on a horizontally-tracked single axis system at 33 deg latitude.

FIG. 42 is a cross-sectional view of a single toroidal arc lens segment, illuminated by two bundles of rays representing the two extreme illumination cases shown in FIG. 39.

FIG. 43 is a cross-sectional view of a single toroidal arc lens segment, where the refractive surfaces are tilted and illuminated by winter solstice noon rays.

FIG. 44 is a cross-sectional view of a three adjacent tilted toroidal arc lens segments, where the center element is illuminated by four ray bundles, two of which represent seasonal extremes at 33 deg latitude. The structure adjoining adjacent toroidal arc lenses is not shown.

FIG. 45 shows three F/0.5 parabolic troughs, each tracked a different way: dual-axis, polar axis, and horizontal N-S axis. On-axis rays are shown.

FIG. 46 shows three F/0.25 parabolic troughs, each tracked a different way: dual-axis, polar axis, and horizontal N-S axis. On-axis rays are shown.

FIG. 47 shows two different toroidal arc lens segments, each designed for operation with parabolic troughs of different focal ratios.

FIG. 48 illustrates the range of ray angles incident on a flat cell card illuminated by an F/0.25 parabolic trough and corresponding toroidal arc lens array. A flat cell plane receives edge rays at near glancing incidence. Sun rays are on-axis.

FIG. 49 illustrates the range of ray angles incident on a V-shaped cell card illuminated by an F/0.25 parabolic trough and corresponding toroidal arc lens array. The parabolic trough segments do not have a common line focus. Each side comes to its own line focus, each substantially centered on the nearest facet of the V-shaped cell card. Maximum incidence angles are greatly reduced compared to the flat cell card. Sun rays are on-axis.

FIG. 50 illustrates the range of ray angles incident on a 3-sided cell card illuminated by an F/0.25 parabolic trough and corresponding toroidal arc lens array. The parabolic trough segments do not have a common line focus. In this example, the center two segments have a common focus centered on the bottom facet, while the outer segments illuminate the side facets. Sun rays are on-axis.

FIG. 51 shows a toroidal arc lens array with a 3-sided cell card.

FIG. 52 is an alternate view of FIG. 50, with the line of sight parallel to the overall line focus.

FIG. 53 shows a toroidal arc lens array with a V-shaped cell card.

FIG. 54 is an alternate view of FIG. 53, with the line of sight parallel to the overall line focus.

### DETAILED DESCRIPTION

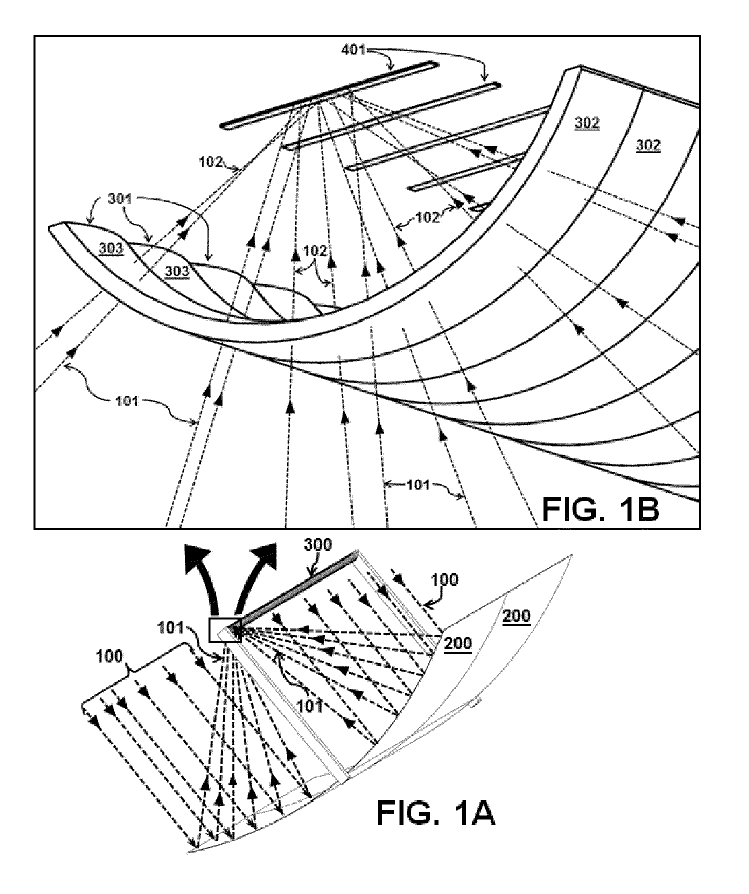

FIG. 1A is a perspective view of a complete optical concentrating system incorporating a toroidal arc lens array. Because the system incorporates optics of large and small scale, for clarity we show the system as a composite on two scales: FIG. 1A shows the whole, and FIG. 1B a detail near the focus. Rays of sunlight 100 are incident on a parabolic cylindrical trough reflector made from segments 200. In this embodiment, the reflector is oriented with the parabolic axis pointed toward the sun. For clarity, only those rays 100 incident close to the end of the trough are shown. The sun rays 100 in this diagram are not strictly parallel, since they emanate from a solar disk of finite angular size. After reflection on the parabolic trough mirror segments 200 the reflected rays 101 are directed to the toroidal arc lens array 300, aligned with the parabolic line focus and supported by structures 203 at either end of the trough.

FIG. 1B shows in detail the end of the toroidal arc lens array 300 which is illuminated by reflected rays 101. The toroidal arc lens segments 301 operate by refraction to provide orthogonal focusing of the rays onto discrete photovoltaic cell arrays 401 of very long aspect ratio. Sunlight rays 101 reflected from the parabolic trough segments 200 reach the outer refracting surface 302, which may in one embodiment be as illustrated, shaped as a circular cylinder. The outer refracting surface 302 may also be curved in cross-section. In this illustration, the cross-section of the surface 302 has infinite radius (straight line). The inner refracting surfaces 303 of each toroidal arc lens segment 301 will in general be aspheric in cross section. In one aspect, the toroidal arc lens segments 301 are revolved extrusions of the aspheric cross section, where the axis of revolution is parallel to the parabolic trough line focus. In another aspect, the toroidal arc lenses may be lofted extrusions, such that the cross-section changes as a function of the rotation angle θ.

FIG. 1 illustrates a preferred embodiment, where the exterior refracting surface 302 is cylindrical so that the toroidal arc lens segments 301 array together into a continuous cylindrical surface. In practice, multiple toroidal arc lens segments may be manufactured as a solid piece of glass or plastic. From the outside, this leaves a smooth cylindrical surface, which is more conducive to cleaning. As with any optical system, a mechanical enclosure is required to fixture the optics and protect the sensitive inner parts from the elements. These mechanics are not shown, but one with ordinary skill in optomechanics would be able to mount and enclose the optical system described here, leaving only the outer refracting surface 302 exposed to the elements.

In the preceding illustrations and descriptions that follow, we will assume that the parabolic trough segments 200 are off-axis segments of a reflecting trough with focal length 1.7 m. The mirror segments 200 have a clear aperture of 1.7 m square. These dimensions are similar to widely-used tempered glass mirrors common to solar thermal plants. This system scaling is illustrative, and does not limit the system to 1.7 m troughs.

Embodiment with Dual-Axis Tracking

For the invention as described above, with the optics and cells held in fixed relationship to each other, the assembly must be mounted on a dual-axis tracker so that the solar collector remains pointed directly at the sun throughout the day. In the examples which follow, this tracking is performed with a vertical azimuth axis surmounted by a horizontal elevation axis. However, effective dual axis tracking can be achieved with any two non-parallel axes. The azimuth-elevation embodiment shown does not limit the invention to any particular implementation of dual-axis tracking.

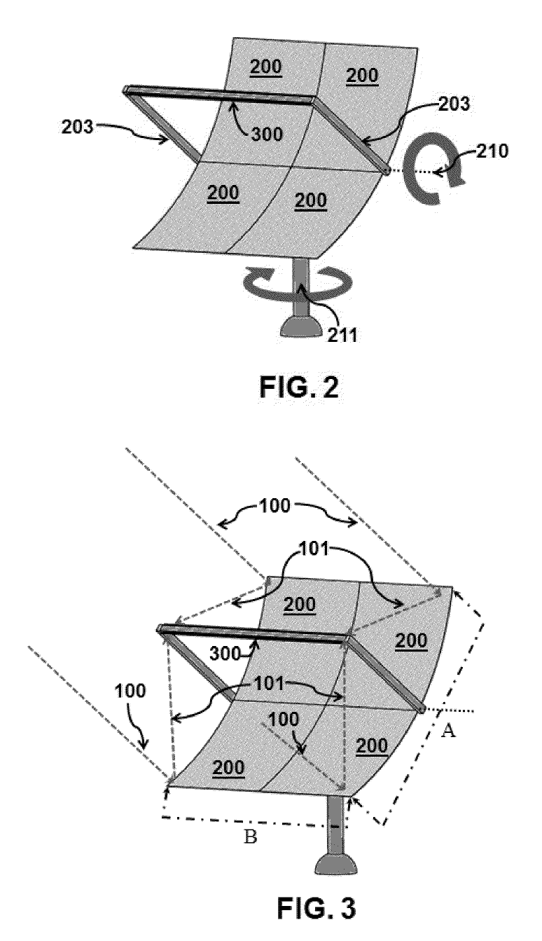

FIG. 2 is a perspective view of a small, illustrative mount supporting a parabolic trough composed of four mirror segments 200. The trough is tracked about an azimuthal axis 211 and an elevation axis 210, allowing the trough to directly face the sun in any part of the sky. This arrangement is not common to parabolic troughs, which are typically tracked about a single axis, either horizontal or parallel to the polar axis. Any parabolic trough system, whether driving a thermal receiver or the photovoltaic generator of the present invention, supports the receiver with a support structure 203, designed to maintain the receiver position while minimizing shadowing. The support structure 203 in this figure and those that follow is for illustration only—much better designs which minimize obscuration in off-axis illumination conditions are preferred. A toroidal arc lens array 300 spans the line focus of the parabolic trough.

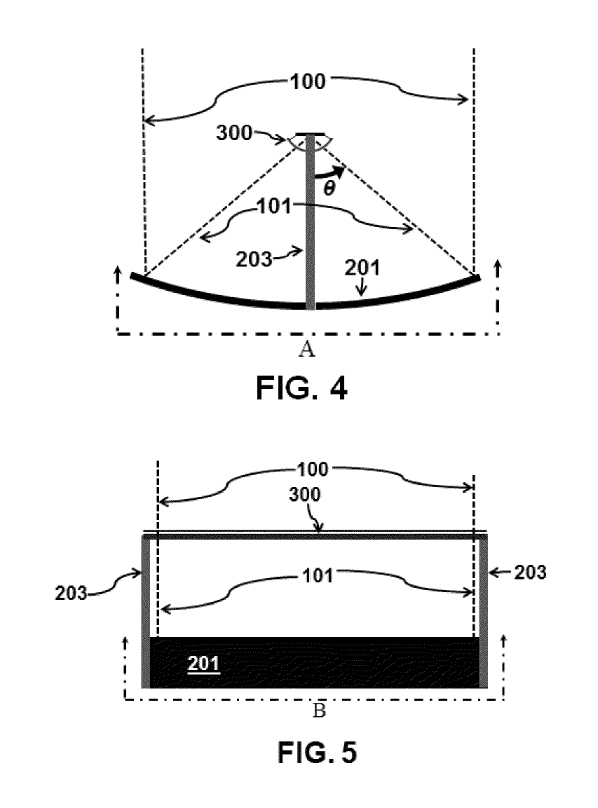

FIG. 4 shows the parabolic trough of FIG. 3 with a line of sight parallel to the overall line focus. Since the trough is two segments wide, the entrance aperture is 3.4 m across. Thus, this trough (with focal length 1.7 m) operates at a focal ratio of F/0.5. The angle θ subtended by the reflected sun rays 101 from the parabola axis is 53.1 degrees for this case. Perfect elevation tracking would keep the line focus centered on the toroidal arc lens array 300.

FIG. 5 views the parabolic trough of FIG. 3 with a line of sight perpendicular to the plane formed by the parabola axis and line focus. With perfect azimuthal tracking, the line focus remains centered between the neighboring support structures 203. Thus, the incident rays 100 and reflected rays 101 overlap in this line of sight.

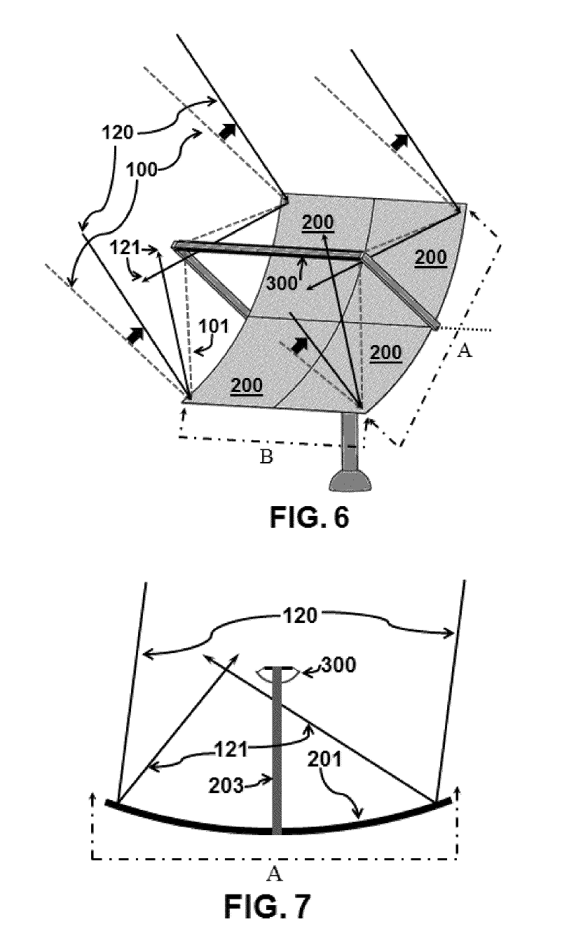

FIG. 6 is a the same parabolic trough as that depicted in FIG. 3, with the addition of four off-axis rays 120 which are mispointed in the zenithal direction. Error in this direction results in a lateral line focus displacement away from the nominal position. The new aberrated line focus, approximately located at the intersection of reflected rays 121, remains centered longitudinally between support structures 203, but misses the toroidal arc lens array 300. In solar thermal plants, where the receiver is an absorber tube, this error results in sunlight missing the absorber.

FIG. 7 views the parabolic trough and off-axis rays of FIG. 6 with a line of sight parallel to the overall line focus. Zenithal error of sufficient magnitude will cause the sunlight to miss the toroidal arc lens array 300, as illustrated. Zenithal error of lesser magnitude may still allow rays to reach the toroidal arc lens array 300, but the resulting irradiance distribution is altered.

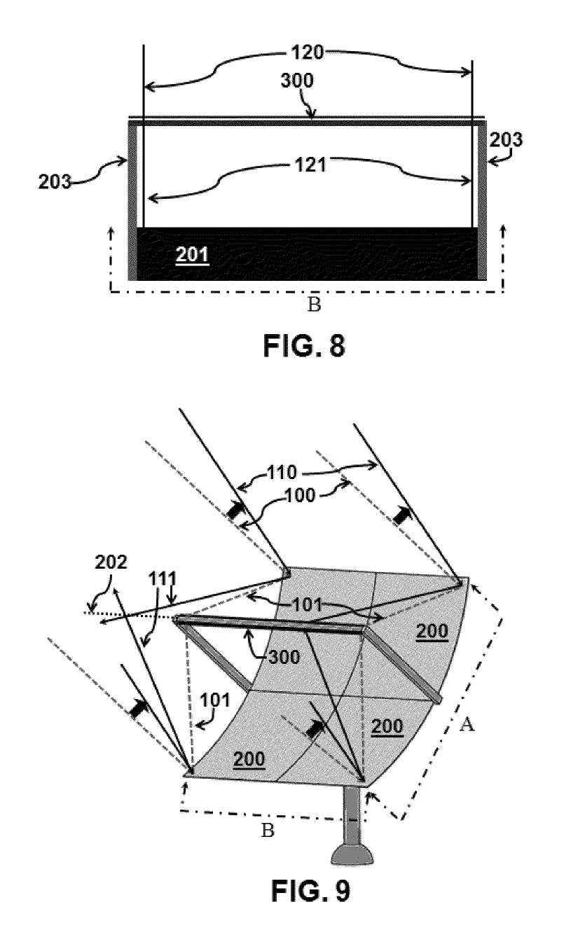

FIG. 8 views the parabolic trough and off-axis rays of FIG. 6 with a line of sight perpendicular to the plane formed by the parabola axis and line focus. Since the error is out of the plane of this illustration, the off-axis rays 120 and reflected rays 121 have the same apparent path as on-axis rays 100 and reflected rays 101 of FIG. 5.

FIG. 9 is a the same parabolic trough as that depicted in FIG. 3, with the addition of four off-axis rays 110 which are mispointed in the azimuthal direction. Error in this direction results in a line focus displacement parallel to the line focus. The shifted line focus, bounded by the intersection of reflected rays 111 from the four corners of the aperture, remains colinear with the nominal line focus. In the small parabolic trough shown, a certain length of the toroidal arc lens array 300 is not illuminated, while light from the other end of the trough spills past the support structure and is lost. In solar thermal plants, troughs are usually hundreds of meters long. Any azimuthal error causes an un-illuminated region at one end of the receiver tube, which for long troughs is a very small percentage of the total length. Thus, thermal trough systems are very tolerant to azimuthal errors, since the tube is illuminated along almost all of its length.

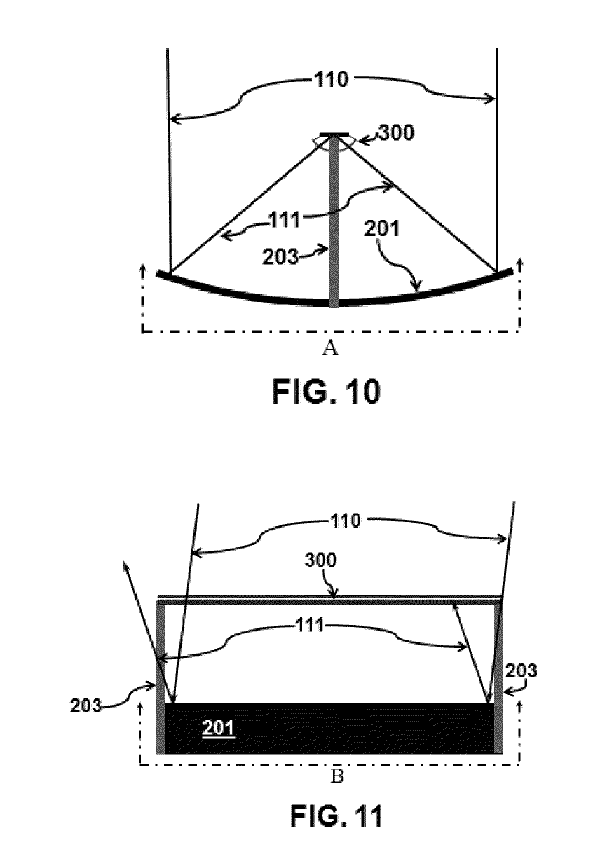

FIG. 10 views the parabolic trough and off-axis rays of FIG. 9 with a line of sight parallel to the overall line focus. Azimuthal error keeps the line focus collinear with the nominal position. Thus, off-axis rays 110 and reflected rays 111 appear from this line of sight no different than the on-axis rays of FIG. 4.

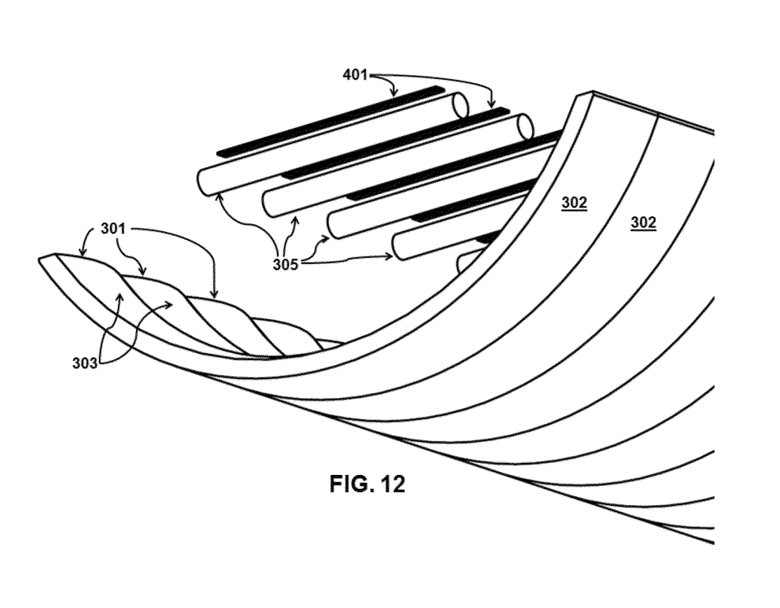

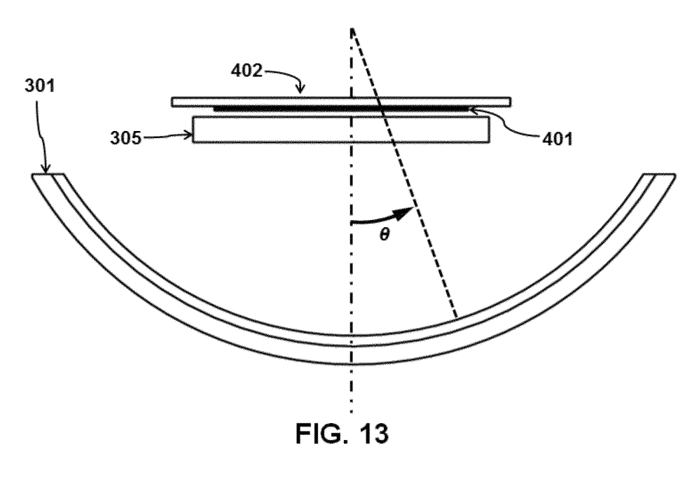

FIG. 11 views the parabolic trough and off-axis rays of FIG. 9 with a line of sight perpendicular to the plane formed by the parabola axis and line focus. One end of the toroidal arc lens array 300 is not illuminated, while the reflected rays 111 are reflected out of the system at the other end. As discussed above, this does not amount to a significant fractional loss if the azimuthal errors are small or if the trough is very long. In the dual-axis tracking case embodied here, the errors should be less than 1°, resulting in a very small obscured region. It may be wise to slightly undersize the toroidal arc lens array 300 such that the trough 201 is slightly longer. This guarantees full illumination of the toroidal arc lens array 300 even with small azimuthal errors.

FIG. 12 is a perspective view of a toroidal arc lens array embodiment composed of multiple toroidal arc lens segments 301, each paired with a rod lens 305 which are oriented perpendicular to the overall parabolic line focus. Behind each rod lens is placed a photovoltaic cell array 401 of very long aspect ratio. The cells 401 may be composed of multiple cells connected in parallel. The toroidal arc lenses 301 operate through two refractions. First, reflected sunlight from the parabolic trough reaches the outer refracting surface 302, which may in one embodiment be a cylinder. In the cylinder case, the cross-section has infinite radius (straight line). The inner refracting surfaces 301 may be aspheric in cross section. The toroidal arc lens segments 301 are revolved extrusions of the cross sections, where the axis of revolution is parallel to the parabolic trough line focus. Alternatively, the toroidal arc lenses may be lofted extrusions, such that the cross-section changes as a function of angle θ. FIG. 12 illustrates a preferred embodiment, where the exterior refracting surface 302 is cylindrical so that the toroidal arc lens segments 301 array together into a continuous cylindrical surface. In practice, multiple toroidal arc lens segments may be manufactured as a solid piece of glass or plastic.

FIG. 13 is an alternate view of FIG. 12, with a line of sight parallel to the overall line focus. This view also shows the cell card 402 onto which the cells 401 are mounted. In this embodiment, which is not limiting, the toroidal arc lens segments 301 have an axis of symmetry which is above the cell card 402. This axis is parallel to the overall line focus, which is perpendicular to the plane of the drawing. A cross-section of the toroidal arc lens segments 301 taken in any plane swept through the angle θ shown will be the same in this embodiment. In other embodiments, the cross-sectional prescription of the toroidal arc lens segments 301 may change as a function of 0, although this greatly complicates lens fabrication.

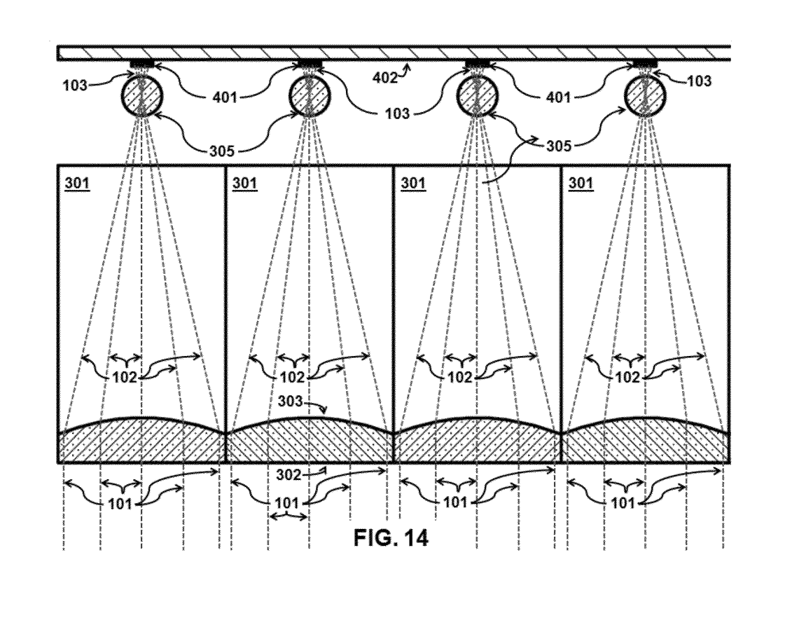

FIG. 14 is a cross-sectional view of FIG. 13, with reflected on-axis rays 101 added. The cross section taken is the plane defined by θ=0°. In this preferred embodiment, the cross section of the exterior refracting surface 302 is flat, such that the toroidal arc lens segments 301 array together into a continuous cylindrical surface. The reflected rays 101 are already converging in one dimension, a convergence which is not apparent from this line of sight. The toroidal arc lens refracting surfaces 302 and 303 function to further concentrate the sunlight in the unfocused direction. The toroidal arc lens segments 301 image the surface of the parabolic trough segments 200 to the center of the rod lenses 305. The refracted rays 102 thus converge in two dimensions. The illustrative reflected rays 101 are strictly on-axis, and do not account for the angular size of the sun, which spans approximately 0.5 degrees. When the sun width is included, the toroidal arc lenses produce a 1D sun image of finite width within the rod lens 305. The on-axis refracted rays 102 produce a sharp focus within the rod lens 305. The rod lenses 305 act to stabilize the irradiance patterns on the cells 401. This stabilization is achieved because the rod lens images the exit aperture of the toroidal arc lens onto the outline of the photovoltaic cell 401. The rod lens does not substantially deviate the on-axis refracted rays 102, since the projection of the incidence angles in the plane perpendicular to the rod lenses is close to zero.

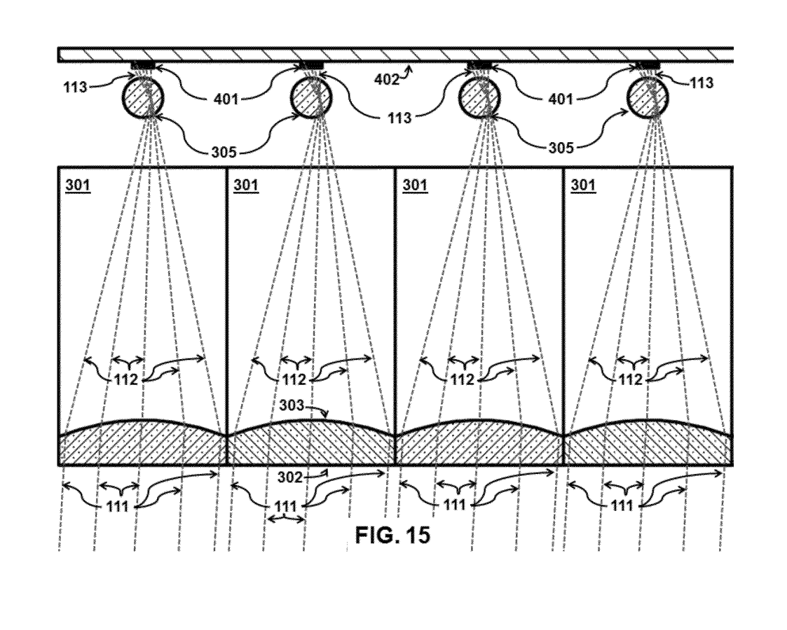

FIG. 15 is the same cross-sectional view of FIG. 14, with reflected off-axis rays 111 added. The off-axis rays 111 are mispointed in the azimuthal direction. This results in a lateral translation of the refracted off-axis rays 112, which shifts the 1D sun image within the rod lens 305. However, the rod lens 305 redirects the rays onto the photovoltaic cell 401. This stabilization is possible due to the imaging conjugation between the outline of the toroidal arc lens segments 301 and the solar cells 401.

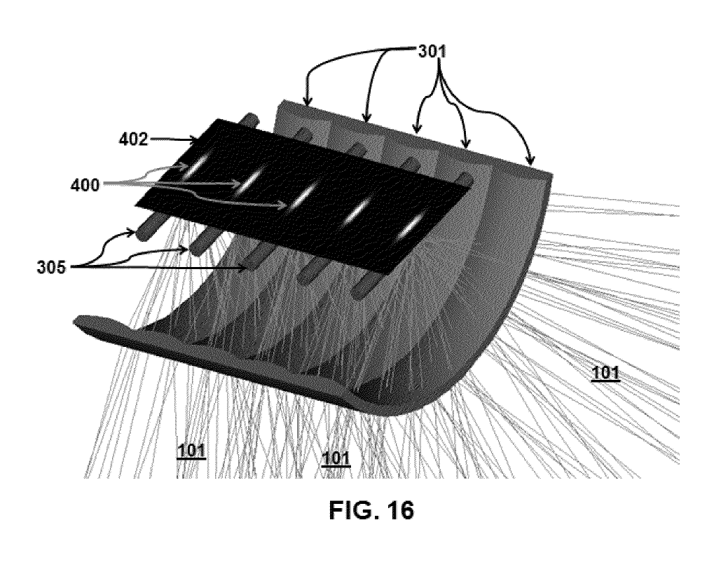

FIG. 16 is a perspective view of a toroidal arc lens array 300 composed of five toroidal arc lens segments 301, each paired with a rod lens 305, illuminated by an F/0.5 parabolic trough to give a series of high concentration foci 400. Illustrative rays, uniformly sampled from the full angular size of the sun are propagated through the model to show a simulated irradiance pattern at the cell plane.

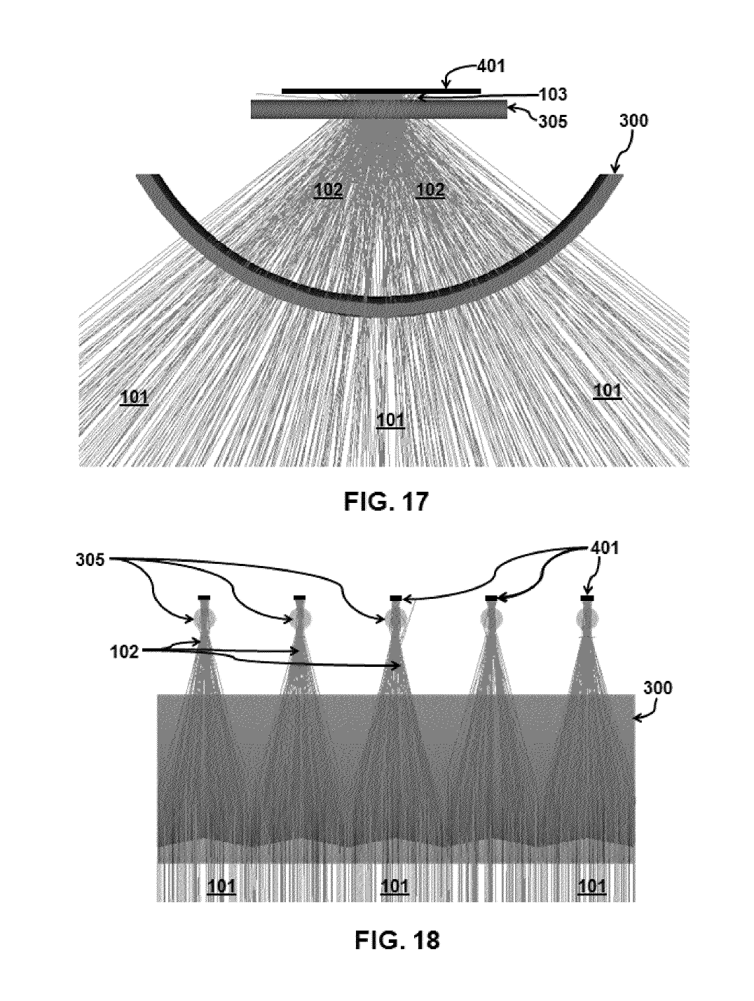

FIG. 17 is an alternate view of FIG. 16, with a line of sight parallel to the overall line focus. This view also shows the cells 401 which receive the concentrated illumination. Reflected on-axis sun rays 101 are from an F/0.5 parabolic trough. The width of the 1D sun image produced by the parabolic trough is a function of the trough focal length and the angular size of the sun. If we take f=1.7 m and the angular subtense of the sun to be 0.5 degrees, then the width of the sun image formed by the parabolic trough's reflective power, wₚ, is wₚ≈2*tan(0.25°)*1.7 m=15 mm. The photovoltaic cell 401 in this example is 60 mm long in this dimension. The oversizing is provided to allow tolerance for mirror errors, toroidal arc lens defects, and tracking errors in the zenithal direction. Note that in the absence of the toroidal arc lens array 300 and rod lenses 305, the trough would produce a low concentration focus in the plane of the cells 401. This low concentration line focus would form along the axis perpendicular to the drawing and centered on the cell 401. The introduction of the toroidal arc lens array 300 and rod lenses 305 break up the low concentration focus into a series of high concentration foci, which are elongated along the length of the cells 401.

FIG. 18 is an alternate view of FIG. 16, with a line of sight parallel to the axis of the rod lenses 305. When illuminated by on-axis reflected sun rays 101, the toroidal arc lens segments 301 form an elongated sun image within the rod lenses 305. The width of the sun image within the rod lenses 305 is a function of the angular size of the sun and the refractive power of the toroidal arc lens segments 301. In this example, the toroidal arc lens segment 301 brings the reflected on-axis rays 101 to a best focus within the rod lens 305 a distance 65 mm from the inner refracting surface 303. The minimum width of the sun image within the rod lens 305 is thus w_{b}=2*tan(0.25°)*65 mm=0.57 mm. The actual width is larger since there is variation is the distance from the rod lens 305 to the toroidal arc lens segment 301 over the angular acceptance range. The rod lenses in this example are 6 mm in diameter, and serve to image (in one dimension) the outline of the paired toroidal arc lens segment 301 to the outline of the photovoltaic cell 401. The PV cells 401 in this example have a 2.5 mm width. Since the toroidal arc lens segments 301 in this example are 25.4 mm wide, the imaging conjugation operates at a magnification of ˜1:10.

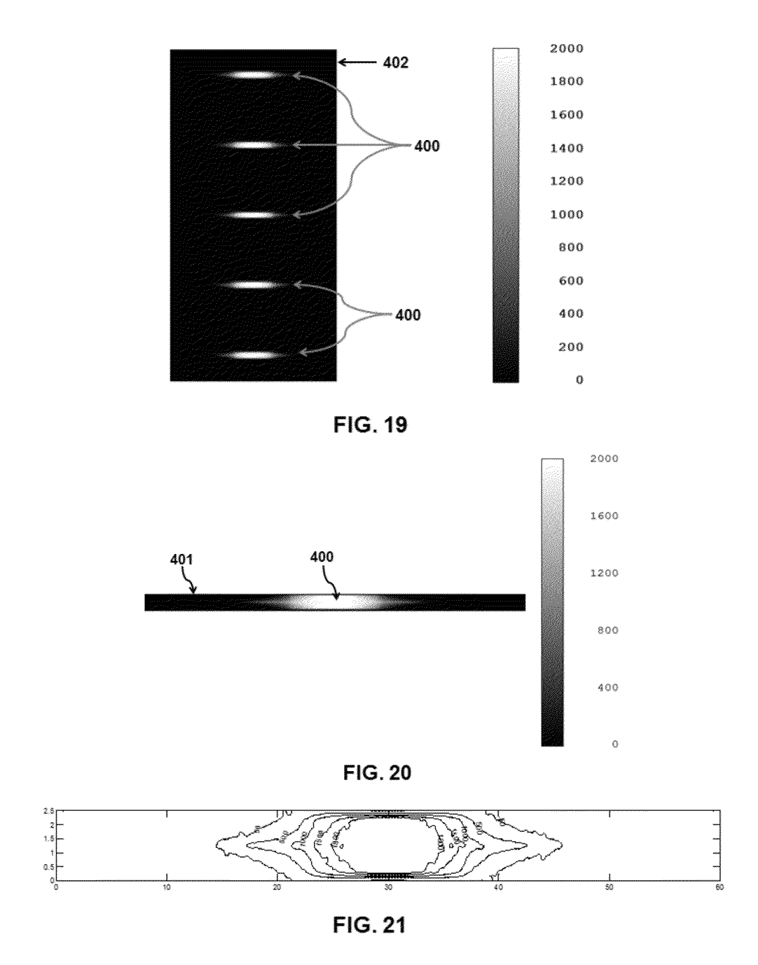

FIG. 19 is the simulated solar irradiance distribution on the cell plane card 402 when the illustrative five-lens system of FIG. 16 is illuminated with on-axis solar radiation. In the full system, photovoltaic cells 401 only cover small strip-shaped areas of the region shown.

FIG. 20 is the solar irradiance distribution on a single cell strip 401 of the exemplary system represented in FIGS. 16-18. The photovoltaic cell 401, with dimensions 2.5 mm by 60 mm, is underfilled by the high concentration line focus 400. The lengthwise excess compensates for tracking errors in the zenithal direction. In this example, the average concentration at the cell, including optical Fresnel losses, is 500×. This assumes no anti-reflection coatings have been applied to the optical surfaces. The geometrical concentration (not including any Fresnel losses) is ˜575×. This is calculated from the ratio of the cell area and the portion of the parabolic trough aperture to which it is conjugated: 3.4 m*25.4 mm/(60 mm*2.5 mm)=575. The oversized cell 401 also allows for greater tolerance to manufacturing defects in the parabolic trough segments 200, toroidal arc lens segments 301, rod lenses 305, and their respective mechanical alignment. By using a shorter cell array 401 and tightening tracking tolerances, average concentrations above 1000× can readily be achieved.

FIG. 21 is an alternate representation of the solar irradiance distribution of FIG. 20, with labeled contours of equal concentration.

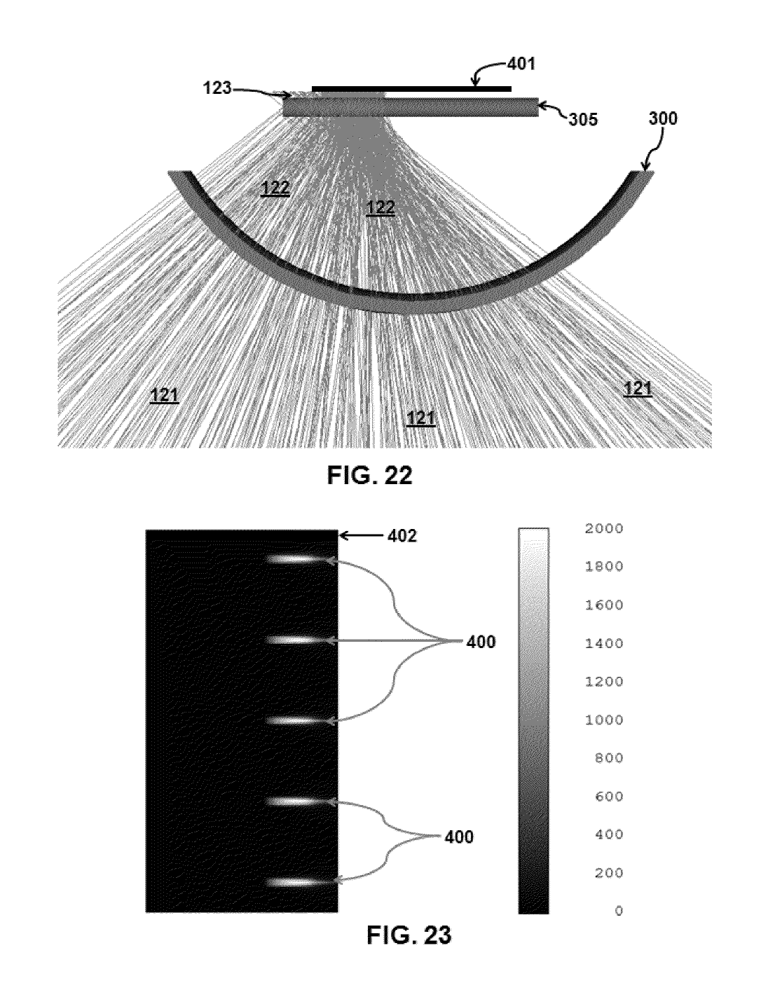

FIG. 22 shows the toroidal arc lens array of FIG. 16, but illuminated with off-axis rays 121 which are mispointed in the zenithal direction by 0.5 degrees. The five toroidal arc lens segments 301, each paired with a rod lens 305, are illuminated by an F/0.5 parabolic trough. Zenithal errors cause a lateral translation of the overall line focus. The toroidal arc lens segments 301 refract the reflected off-axis rays 121, producing refracted off-axis rays 122 which converge at one end of the rod lenses 305. The displacement due to zenithal ray errors, Δ_{z}, is a function of the parabolic trough focal length, f_{T}, and zenithal ray error, δ_{z}, and is given by Δ_{z}≈f_{T}*tan(δ_{z}) for small ray errors. Thus, in this example, the centroid is displaced Δ_{z}≈1.7 m*tan(0.5°)=14.8 mm. This is merely an approximation, since the off-axis rays are also aberrated, forming an imperfect 1D sun image. After the refracted rays 122 pass through the rod lenses 305, some of the refracted rays 123 miss the photovoltaic cells 401.

FIG. 23 is the simulated solar irradiance distribution on the cell plane card 402 when the illustrative five-lens system is illuminated with the off-axis rays 121 shown in FIG. 22. The high concentration line foci 400 are longitudinally displaced and aberrated compared to the on-axis illumination condition (FIG. 19).

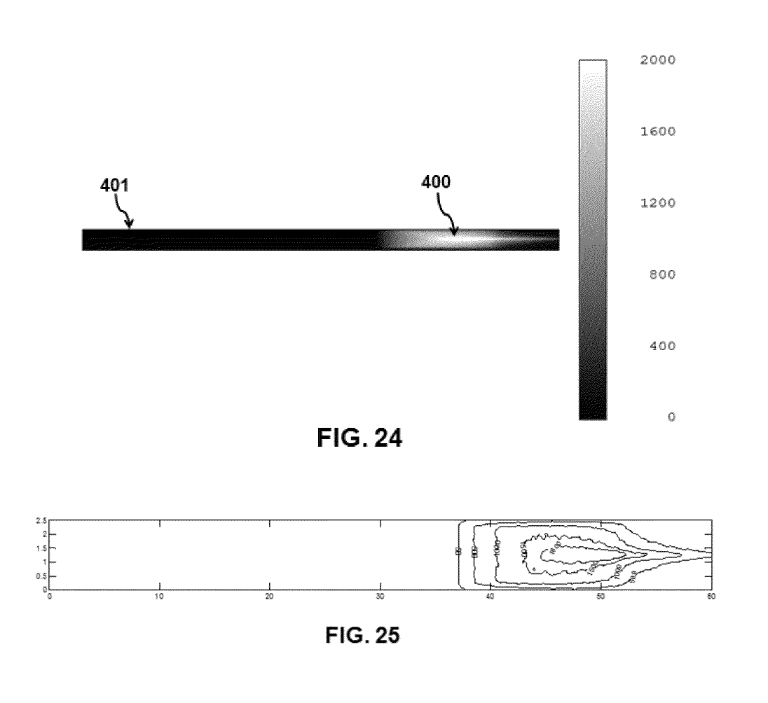

FIG. 24 is the solar irradiance distribution on a single cell strip 401 of the distribution shown in FIG. 23. The photovoltaic cell 401 is underfilled in this illumination case. Most of the excess cell length is to accommodate zenithal errors, such as the 0.5 degree zenithal error represented here.

FIG. 25 is an alternate representation of the solar irradiance distribution of FIG. 24, with labeled contours of equal concentration.

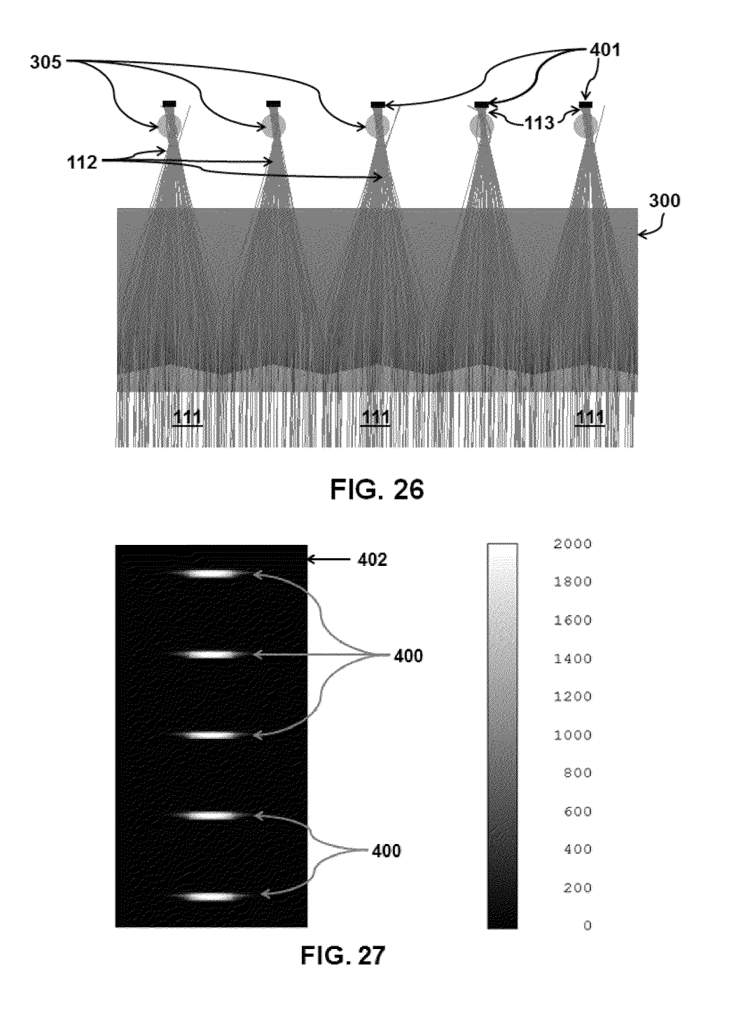

FIG. 26 shows the toroidal arc lens array of FIG. 16, but illuminated with off-axis rays 111 which are mispointed in the azimuthal direction by 0.75 degrees. The five toroidal arc lens segments 301, each paired with a rod lens 305, are illuminated by an F/0.5 parabolic trough. Azimuthal errors cause a longitudinal translation of the overall line focus. The toroidal arc lens segments 301 refract the reflected off-axis rays 111, producing refracted off-axis rays 112 which converge off center within the rod lenses 305. The centroid displacement due to azimuthal ray errors, Δ_{A}, is a function of the toroidal arc lens segment focal length, f_{b}, and azimuthal ray error, δ_{A}, and is given by Δ_{A}≈f_{b}*tan(δ_{z}) for small ray errors. Thus, in this example, the centroid is displaced Δ_{A}≈65 mm*tan(0.75°)=0.85 mm. This displacement keeps all but a few refracted rays 112 well within the diameter of the rod lens 305. The rod lenses 305 are positioned such that there is a 1D imaging relationship between the outline of the toroidal arc lens segments 301 and the photovoltaic cell 401. Thus, the centroid of the redirected rays 113 falls on the center of the photovoltaic cell 401.

FIG. 27 is the simulated solar irradiance distribution on the cell plane card 402 when the illustrative five-lens system is illuminated with the off-axis rays 111 shown in FIG. 26 (rays with azimuthal error of 0.75 degrees). The high concentration line foci 400 are well-stabilized by the rod lenses 305 and show minimal distortion compared to the on-axis illumination case shown in FIG. 19.

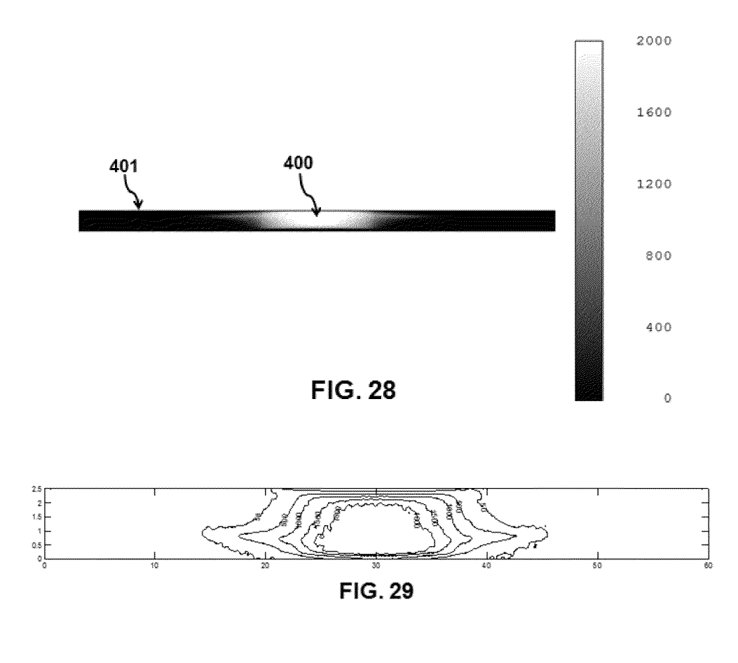

FIG. 28 is the solar irradiance distribution on a single cell strip 401 of the distribution shown in FIG. 27. The high concentration line focus 400 is minimally displaced relative to the on-axis illumination case (FIG. 20). Thus we see that the optical system is very well stabilized against ray errors in the azimuthal direction.

FIG. 29 is an alternate representation of the solar irradiance distribution of FIG. 28, with labeled contours of equal concentration.

The embodiment described above is suitable for a parabolic trough tracked on a dual-axis mount. The rod lenses 305 stabilize the system against azimuthal tracking errors, but are not necessary if sufficiently accurate azimuthal tracking can be assured. A toroidal arc lens array 300 can be coupled directly to photovoltaic cells 401 by placing the cells at the toroidal arc lens focus rather than the rod lenses 305.

In the descriptions of 1D tracking embodiments that follow, the terms ‘azimuthal’ and ‘zenithal’ will be used to describe the ray errors incident on parabolic troughs of different orientations. These terms do not have the same meaning for single-axis tracked systems, since single axis motion often causes a linear combination of the two errors. However, it is convenient to continue using this convention. So ‘azimuthal’ ray error will continue to refer to misalignment which translates the overall line focus longitudinally (down its length), and ‘zenithal’ ray error will continue to refer to ray errors which laterally translate the overall line focus. Azimuthal error causes the line focus to run off the end of the receiver, leaving an unilluminated region at the opposite end. Zenithal error causes the line focus to run off the side of the receiver, equally impacting regions of the receiver over its whole length.

Embodiment for 1D Tracking about a Polar Axis

An alternative to dual-axis tracking is single axis tracking about a polar (or equatorial) axis. This is achieved by orienting the parabolic trough North-South, then tilting the trough towards the equator by the latitude angle of the site. Thus, a system in the northern hemisphere at 33 degrees latitude would tilt a North-South oriented trough by 33 degrees, such that the trough aperture faced the southern sky. In dry, sunny sites in the southwest states of the United States, single axis tracking about a polar axis collects ˜95% of all direct beam solar radiation compared to dual-axis tracking. The 5% loss may be worth the simpler mechanics needed for tracking.

It is understood that the description which follows does not limit the embodiment to tracking about a strictly polar axis. It is common practice to bias the tilt angle away from the latitude angle to improve performance during a certain season. For example, in the northern hemisphere, one would reduce the tilt angle to collect more light in the summer. Likewise, the orientation need not be exactly North-South.

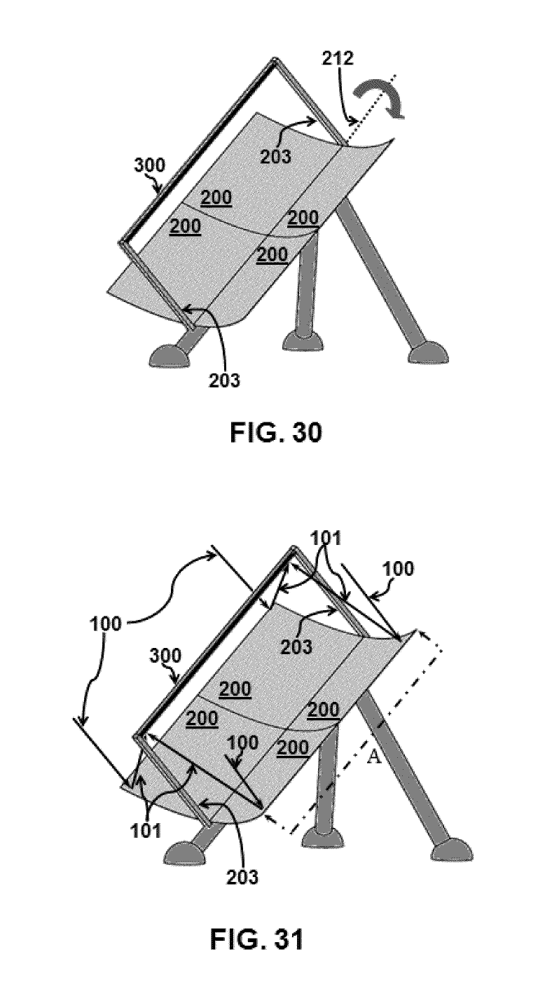

FIG. 30 shows an F/0.5 parabolic trough composed of four parabolic trough segments 200 tracked about a polar axis 212. The toroidal arc lens array 300 and support structure 203 are likewise tilted by the latitude angle.

FIG. 31 shows the F/0.5 parabolic trough of FIG. 30, illuminated by four on-axis rays 100 intercepting the trough aperture near the outer four corners. On the equinoxes, this illumination condition is very nearly maintained the whole day.

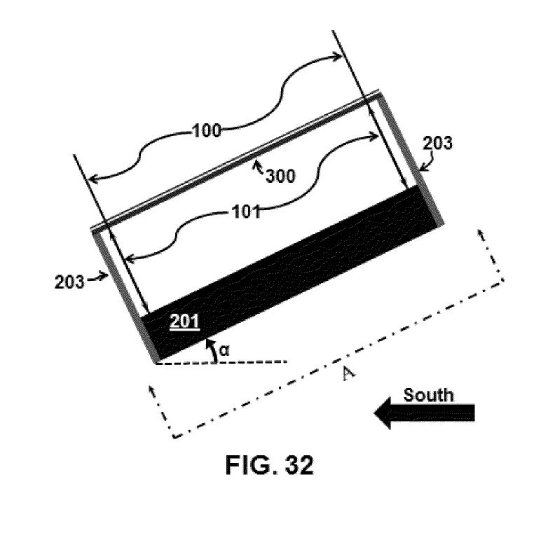

FIG. 32 is a side view of the F/0.5 parabolic trough and on-axis rays 100 from FIG. 31. The tilt angle α is the site latitude.

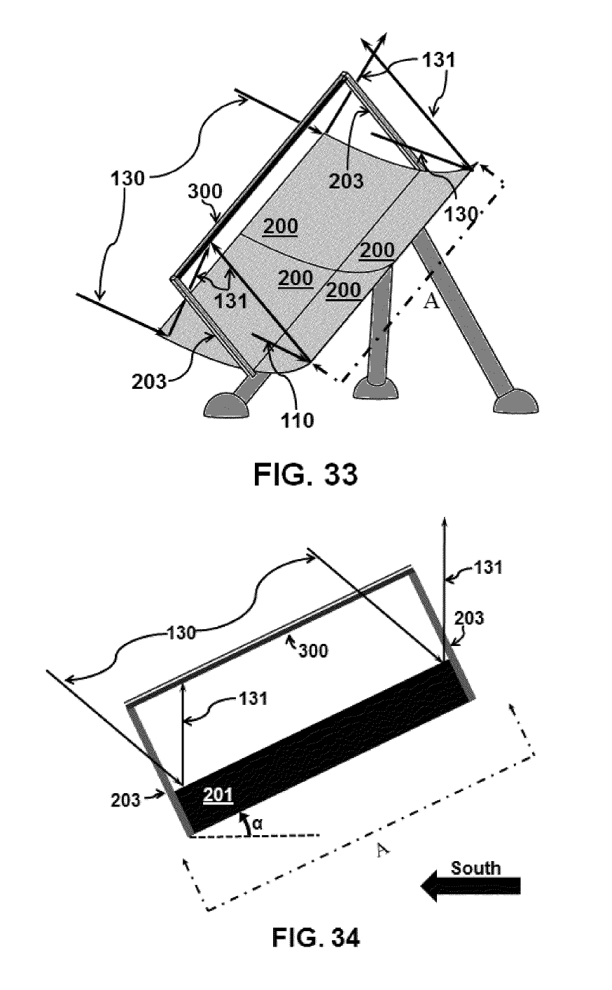

FIG. 33 shows an F/0.5 parabolic trough composed of four parabolic trough segments 200 tracked about a polar axis 212. The trough, located in the northern hemisphere, is illuminated by four off-axis rays 130 from the winter solstice noon condition (mispointed in the azimuthal direction by 23.5 degrees). In this seasonal extreme, the lower end of the toroidal arc lens array 300 is not illuminated. At the opposite end of the trough, reflected sun rays 111 spill over the end of the toroidal arc lens array 300. The length of non-illuminated region of the receiver is found by d=f_{T}*tan(23.5°)=739 mm. For the small four-segment trough illustrated, this obscured region represents 21.7% of the total toroidal arc lens array length. In practice, a much longer trough would be implemented to reduce this fractional loss.

FIG. 34 is a side view of the trough in FIG. 33. The off-axis winter solstice noon rays 130 shown represent one extreme illumination case. The opposite extreme is experienced during the summer solstice, and leaves an un-illuminated region on the upper end of the toroidal arc lens array 300.

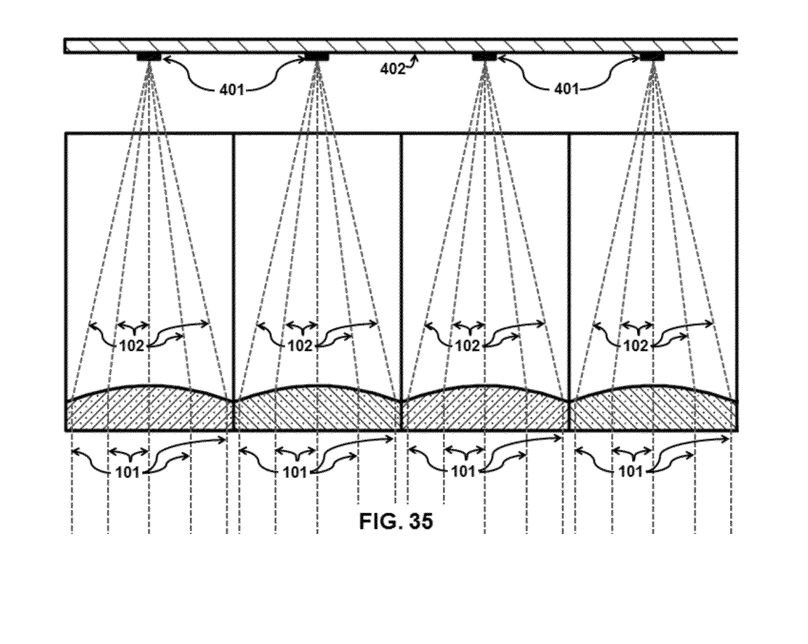

FIG. 35 is a cross-sectional view of a four-segment toroidal arc lens array 300 illuminated by reflected on-axis rays 101. In this embodiment, the rays 102 refracted by the toroidal arc lens segments 301 are directly targeted on the photovoltaic cells. For polar axis tracking, this illumination condition is met during the equinoxes.

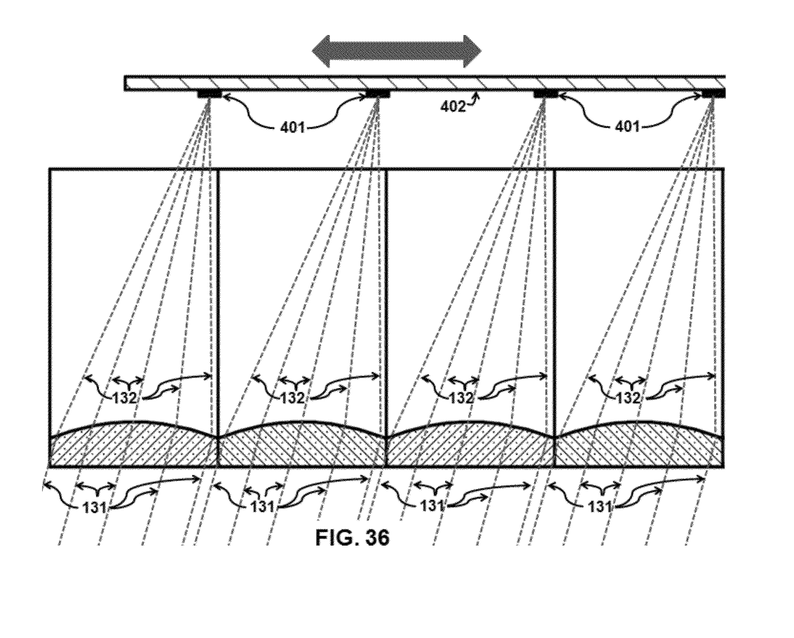

FIG. 36 is a cross-sectional view of a four-segment toroidal arc lens array 300 illuminated by reflected off-axis winter solstice rays 131. The refracted rays 132 come to a displaced focus which is translated by a distance d=f_{b}*tan(23.5°). To keep the photovoltaic cells 401 illuminated, there must be a relative motion between the cell card 400 and the toroidal arc lens array 300. In one embodiment, the toroidal arc lens array 300 is fixed, with the cell cards moved by linear actuation parallel to the overall line focus. Alternately, the cell card 400 may be fixed while the toroidal arc lens array 300 is translated along the line focus by linear actuation. If the required motion is greater than half the toroidal arc lens segment 301 width, one option is to move in the opposite direction such that each toroidal arc lens segment 301 illuminates a neighboring cell 401. This strategy reduces the required linear actuation range, but leaves one cell 401 non-illuminated.

1D Polar axis tracking has the advantage of high collection efficiency while keeping azimuthal incidence angles within a limited, symmetric range (−23.5° to +23.5°). The cosine obliquity factor experienced at either seasonal extreme is only cos(23.5°)=0.917. With an equinox obliquity factor of 1, it is no wonder that the year-averaged collection efficiency is ˜95% compared to dual-axis tracking Another advantage of polar axis tracking is that the incidence angle changes very slowly, remaining nearly the same for days at a time. This allows the linear actuation components to go through very little wear and have short duty cycles.

One problem with polar axis tracking, illustrated in FIG. 34, is that portions of the overall line focus are not illuminated during certain times of the year, especially during seasonal extremes. Long troughs have the advantage of reducing the percentage of line focus which is non-illuminated. However, as the length of the trough and latitude increases, the height of the system above ground level increases. For example, a 17 meter trough (10 segments long) tracked on a polar axis at 33° latitude will rise over 10 meters in the air at the north end. For this reason, large solar thermal parabolic trough plants operate with horizontal single axis North-South tracking, with troughs hundreds of meters long. The embodiment description which follows allows the toroidal arc lens array to operate with a trough tracked about a horizontal axis.

Embodiment for 1D Tracking about a Horizontal Axis

In the desert southwest United States, near 33 degrees latitude, single axis tracking about a horizontal North-South axis collects ˜88% of direct sunlight compared to dual-axis tracking There are several mechanical advantages to single axis tracking on a horizontal axis: uninterrupted troughs can span hundreds of meters and a single drive system can rotate troughs of great lengths. Note that at the equator, tracking about a horizontal North-South axis is equivalent to tracking about a polar axis. With higher latitudes, the annual incidence angle range increases and loses symmetry about 0 degree incidence.

On the equinox, the sun rises exactly due East (90° azimuth, 0° elevation) everywhere in the world. Any North-South trough will illuminate its receiver at 0 degrees incidence at that moment. On the equator, this perfect tracking is maintained during the whole day. In the northern hemisphere, the sun reaches a maximum elevation when at noon (180° azimuth, [90-latitude]° elevation). The incidence angle at this noon equinox is equal to the latitude of the site, and is the maximum for the day.

Tracking about a horizontal axis does not keep the incidence angles near zero (like dual axis tracking), or within a limited, symmetrical range (like polar axis tracking) Instead, the residual azimuthal incidence from single horizontal axis tracking changes significantly throughout the day. One seasonal extreme is the summer solstice dawn/dusk case, where the sun rises in the northeast and sets in the northwest in much of the northern hemisphere. The other extreme case is the winter solstice noon case, where the incidence angle is the sum of the site latitude and 23.5°.

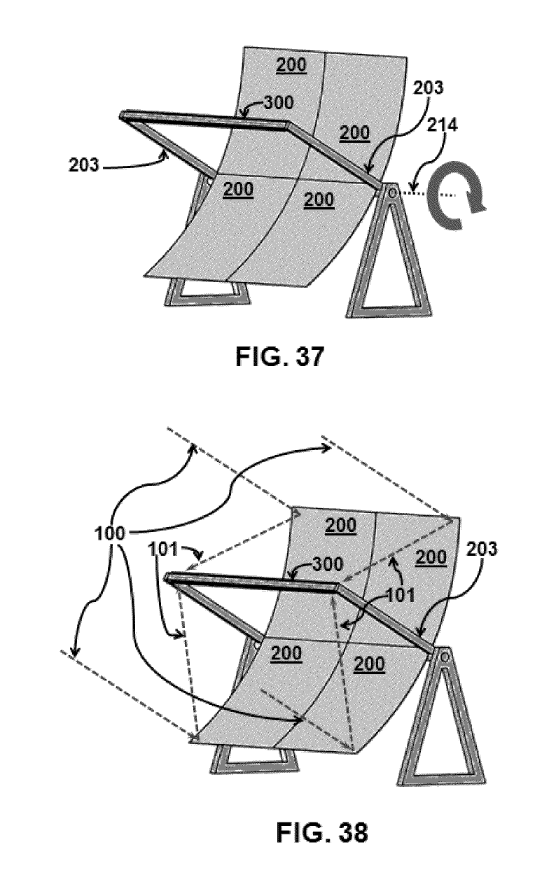

FIG. 37 shows an F/0.5 parabolic trough composed of four parabolic trough segments 200 tracked about a horizontal North-South axis 214. The toroidal arc lens array 300 and support structure 203 are likewise horizontal.

FIG. 38 shows an F/0.5 parabolic trough composed of four parabolic trough segments 200 tracked about a horizontal North-South axis 214, illuminated with four on-axis rays 100. This condition is met several times each year, including at sunrise/sunset on the equinoxes.

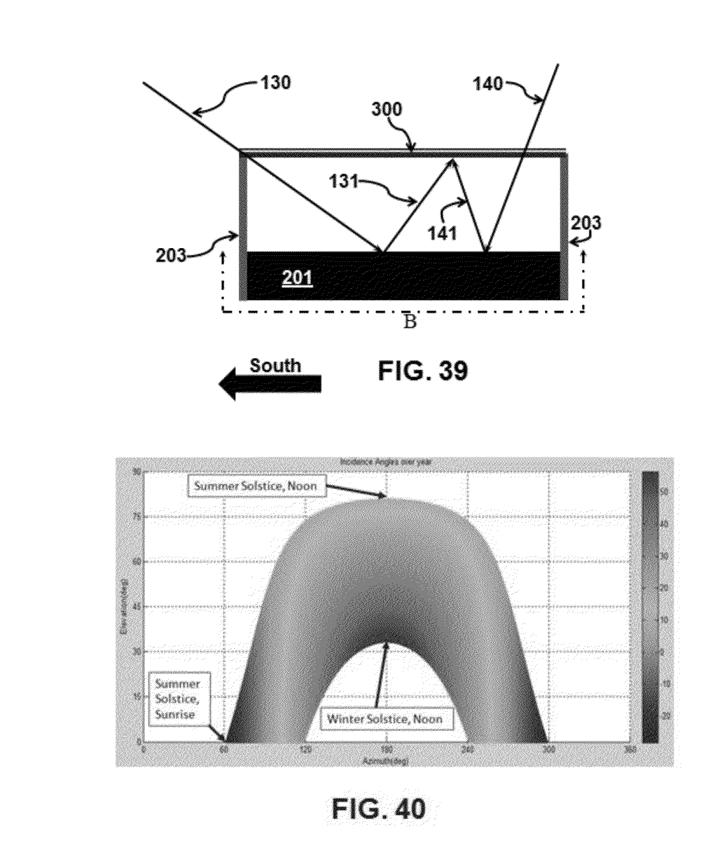

FIG. 39 shows the F/0.5 parabolic trough illuminated by two rays representing the extreme illumination cases at 33 degrees latitude. On the winter solstice at noon, sun ray 130 has a 55° incidence angle on the trough. The cosine obliquity factor on the winter solstice noon is cos(55°)=0.57, a very significant loss. On the summer solstice sunrise, sun ray 140 has a −26° incidence angle on the trough, with a cosine obliquity factor of cos(−26°)=0.90. At this 33° latitude, the angular range over which the toroidal arc lens array 300 must operate is much greater than the polar axis tracking case and is not symmetric about 0°.

FIG. 40 is a graph of sun positions (elevation and azimuth) over the whole year on a parabolic trough tracked about a horizontal North-South axis located near 33 deg latitude. The shaded bar at the right of the drawing indicates off-axis incidence angle on the trough.

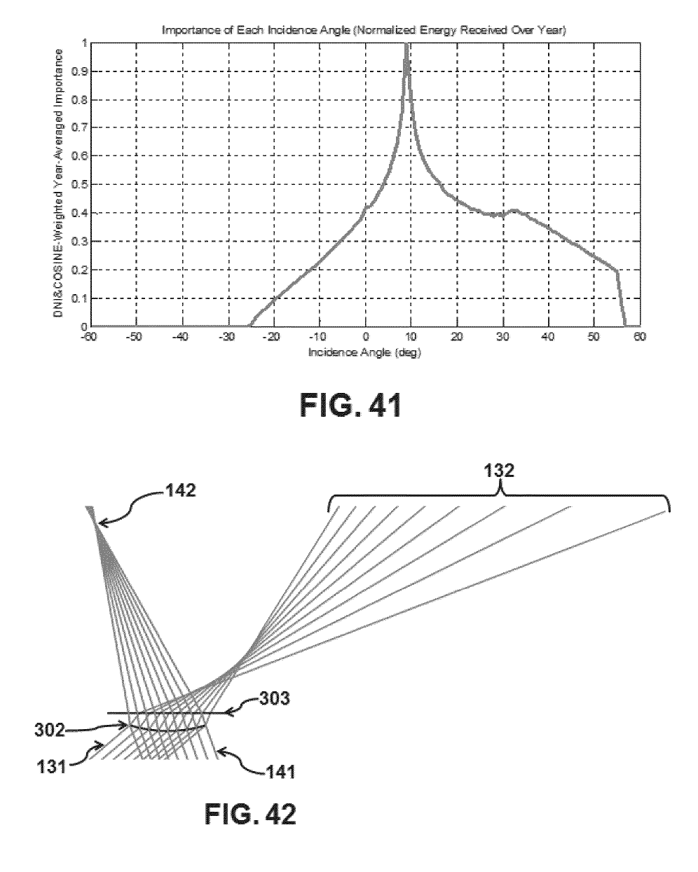

FIG. 41 is the intensity-weighted importance of each incidence angle on a horizontally-tracked single axis system at 33 deg latitude. Not all incidence angles are equally important. For example, the incidence angle is −26° for just a brief period at dawn and dusk right around the summer solstice. Direct sunlight is greatly attenuated at dawn and dusk, making this incidence angle even less important. In designing the toroidal arc lenses it is preferred to achieve the best performance over the most important incidence angles. The sharp peak is due to multiple sunny days surrounding the summer solstice where the midday incidence angle dwells around (latitude−23.5°)=(33°−23.5°)=9.5° for hours at a time.

FIG. 42 is a cross-sectional view of a single toroidal arc lens segment, illuminated by two bundles of rays representing the two extreme illumination cases shown in FIG. 39. The reflected dawn/dusk summer solstice rays 141 are quite manageable, with refracted rays 142 coming to a good focus. The reflected noon winter solstice rays 131 suffer from severe aberrations, with refracted rays 132 failing to form a focus at a plane anywhere near the focus plane for rays 142.

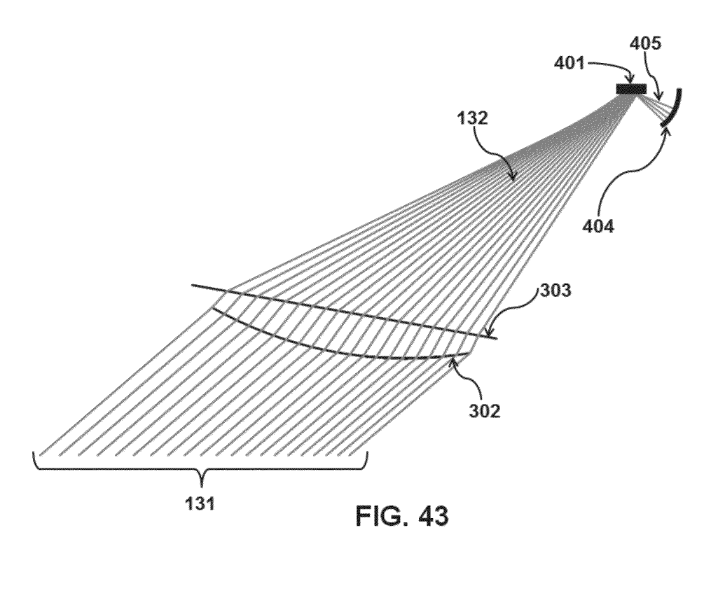

FIG. 43 is a cross-sectional view of a single toroidal arc lens segment, where the refractive surfaces 302 and 303 are tilted and illuminated by reflected winter solstice noon rays 131. Since the incidence angle limits are not symmetric about 0°, optical performance gains can be achieved by tilting the refractive surfaces 302 and 303 such that optimal performance is also non-symmetrical about 0° incidence. Adjacent toroidal arc lens segments 301 require a connecting flange (not shown) since they do not meet edge to edge. The refracted winter solstice rays 132 arrive at the photovoltaic cell 401 at a large incidence angle. Some of the rays 405 which are specularly reflected from the top surface photovoltaic cell 401 would normally be lost. However, if a curved or faceted reflector 404 is positioned to the north side of the cell, along its whole length, some of the rejected light is reflected back to the cell and has a second opportunity to be absorbed. This trick is only possible because the annual incidence angle range is highly asymmetric. Otherwise, the summer solstice dawn rays would be blocked by the reflector 404.

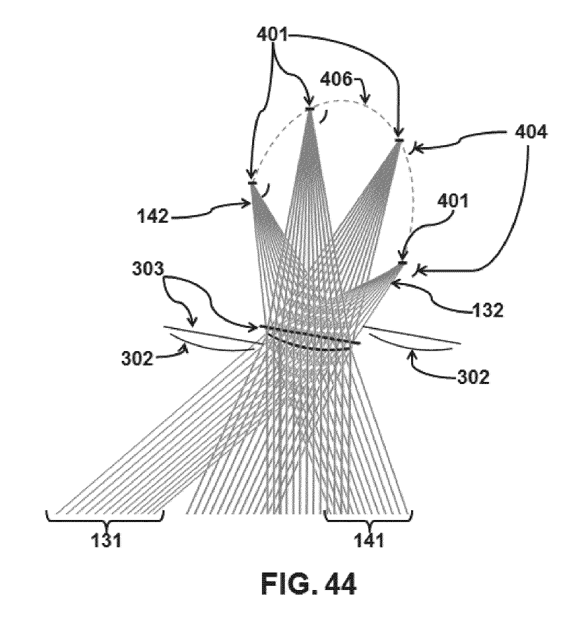

FIG. 44 is a cross-sectional view of three adjacent tilted toroidal arc lens segments 301, where the center element is illuminated by four ray bundles, two of which represent seasonal extremes at 33 deg latitude. The structure adjoining adjacent toroidal arc lenses is not shown. Note that the reflector 404 does not block the rays in any of the four illumination cases. The relative motion between the photovoltaic cells 401 and the toroidal arc lens segments 301 is arc-shaped in this embodiment (dashed line, 406). By actuation in two orthogonal directions, this arced relative motion can be achieved.

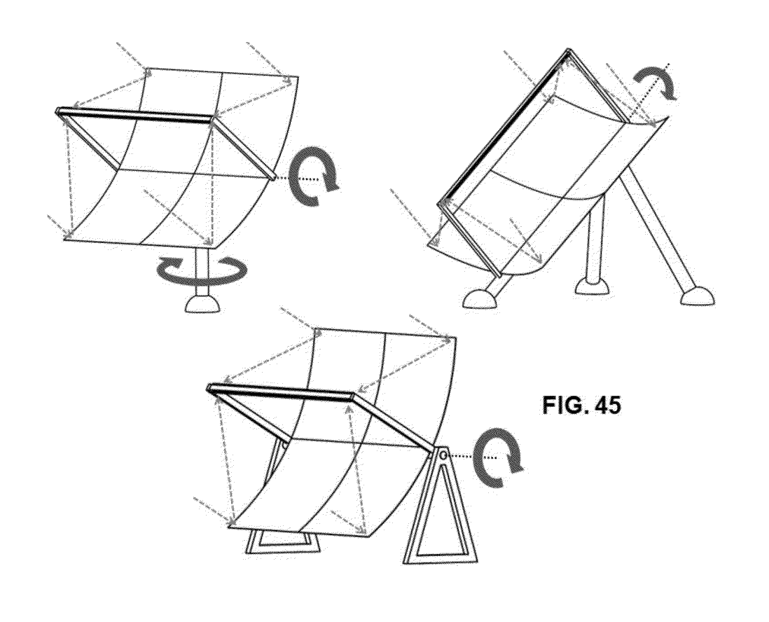

FIG. 45 shows three F/0.5 parabolic troughs, each tracked a different way: dual-axis, polar axis, and horizontal N-S axis. On-axis rays are shown. The angle between reflected rays 101 from opposite sides of the trough is 106°.

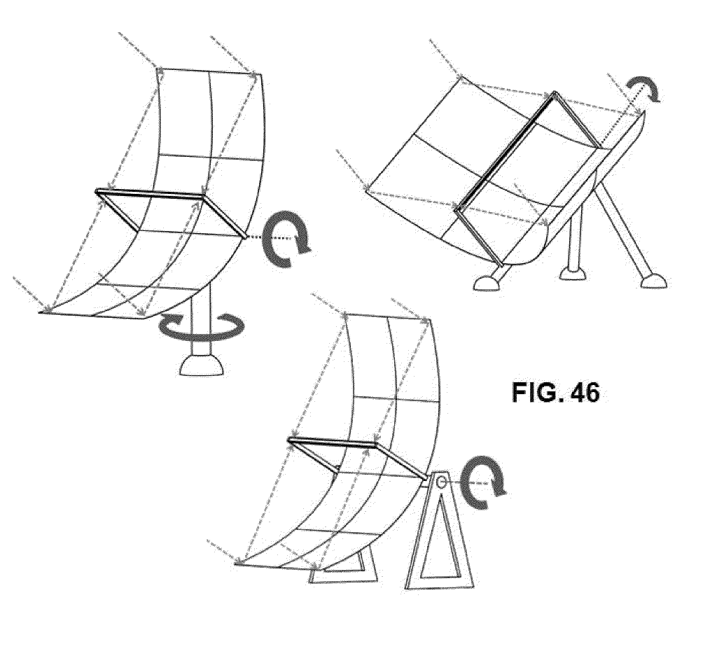

FIG. 46 shows three F/0.25 parabolic troughs, each tracked a different way: dual-axis, polar axis, and horizontal N-S axis. On-axis rays are shown. The angle between reflected rays 101 from opposite sides of the trough is 180°. In other words, the rays are counter-propagating. In solar thermal plants, F/0.25 troughs are common. Since the thermal receivers are cylindrical absorbers, counter-propagating edge rays are not a problem—they simply strike opposite sides of the absorber tube.

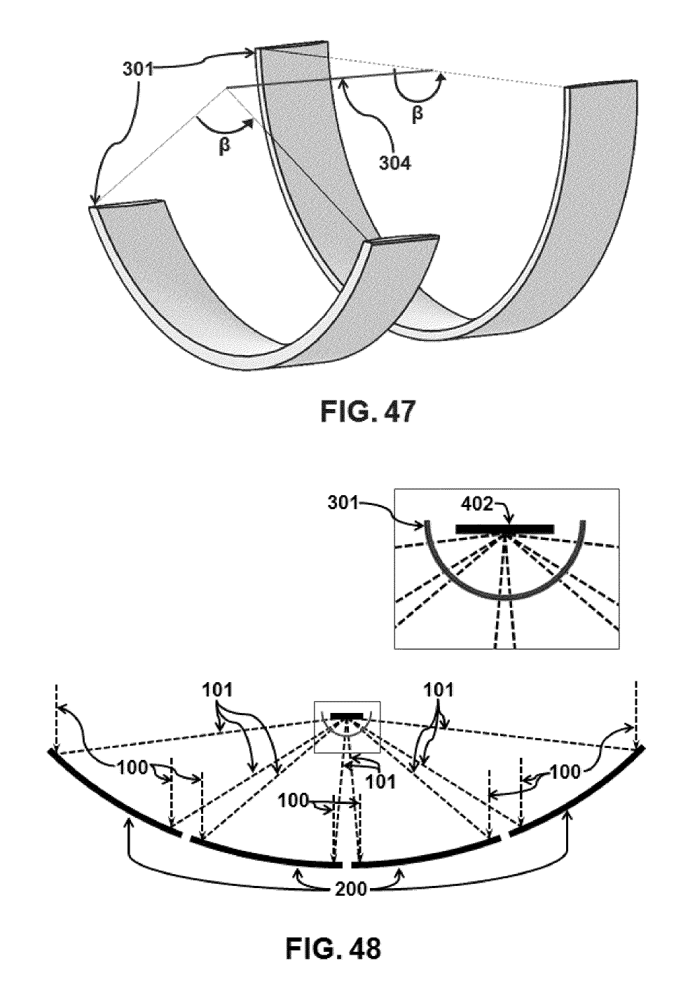

FIG. 47 shows two different toroidal arc lens segments, each designed for operation with parabolic troughs of different focal ratios. The toroidal arc lens segment revolution angle β is determined by the focal ratio of the parabolic trough 201 with which it operates. These illustrative toroidal arc lens segments 301 have symmetry about an axis 304, which is parallel to the overall line focus. The invention is not limited to lenses of complete symmetry about the axis of revolution 304. Performance gains can be achieved by allowing the cross-sectional prescription to change as a function of 0.

FIG. 48 illustrates the range of ray angles incident on a flat cell card 402 illuminated by an F/0.25 parabolic trough and corresponding toroidal arc lens array. The flat cell plane 402 receives reflected edge rays 101 at near glancing incidence. The trough is four segments wide, and all four segments 200 have a common focus.

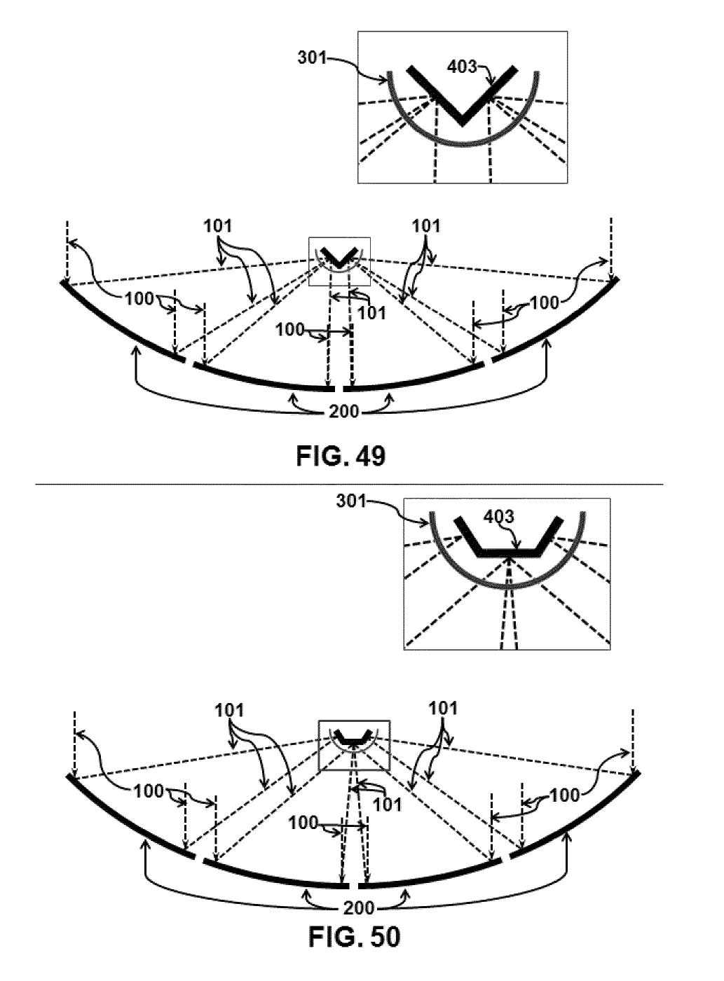

FIG. 49 illustrates the range of ray angles incident on a two-faceted non-planar cell card 403 illuminated by an F/0.25 parabolic trough 201 and corresponding toroidal arc lens array 300. The parabolic trough segments 200 do not have a common line focus. Each side comes to its own line focus, each substantially centered on the nearest facet of the V-shaped cell card 403. Maximum incidence angles are greatly reduced compared to the flat cell card. This embodiment is compatible with any of the three tracking configurations discussed above. The apex angle between the two facets of the non-planar cell card 403 can be adjusted to best match the incoming irradiance distribution from the parabolic trough segments 200.

FIG. 50 illustrates the range of ray angles incident on a three-faceted cell card 403 illuminated by an F/0.25 parabolic trough 201 and corresponding toroidal arc lens array 300. The parabolic trough segments 200 do not have a common line focus. In this example, the center two segments have a common focus centered on the bottom facet, while the outer segments illuminate the side facets.

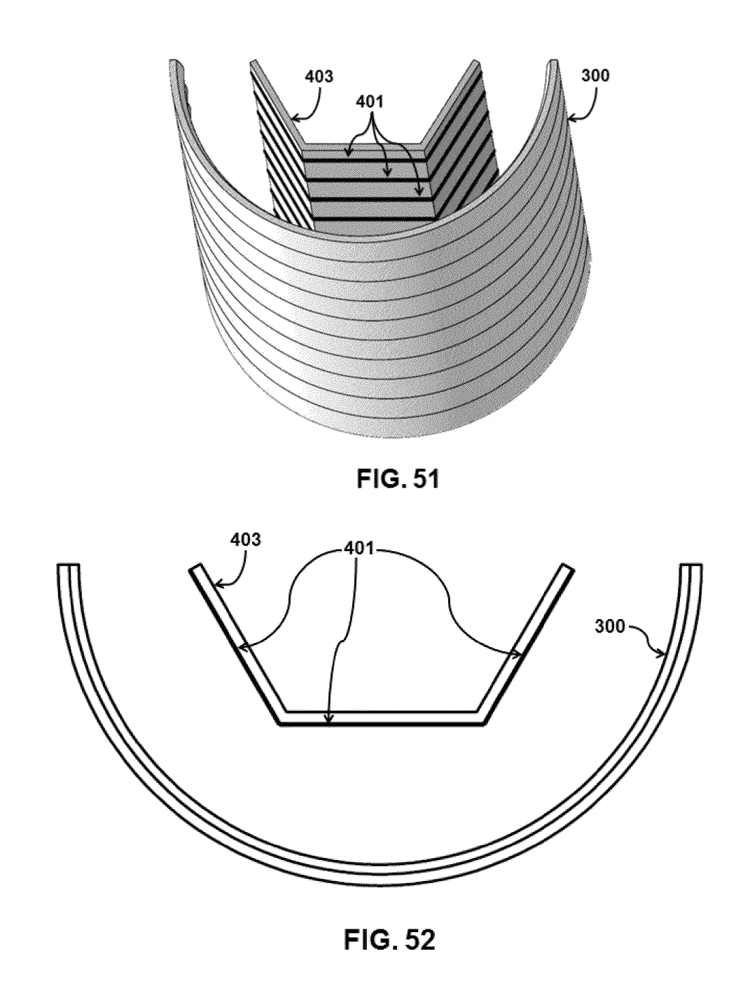

FIG. 51 is an alternate view of a toroidal arc lens array and 3-sided cell card 403 and photovoltaic cells 401.

FIG. 52 is an alternate view of FIG. 50, with the line of sight parallel to the overall line focus.

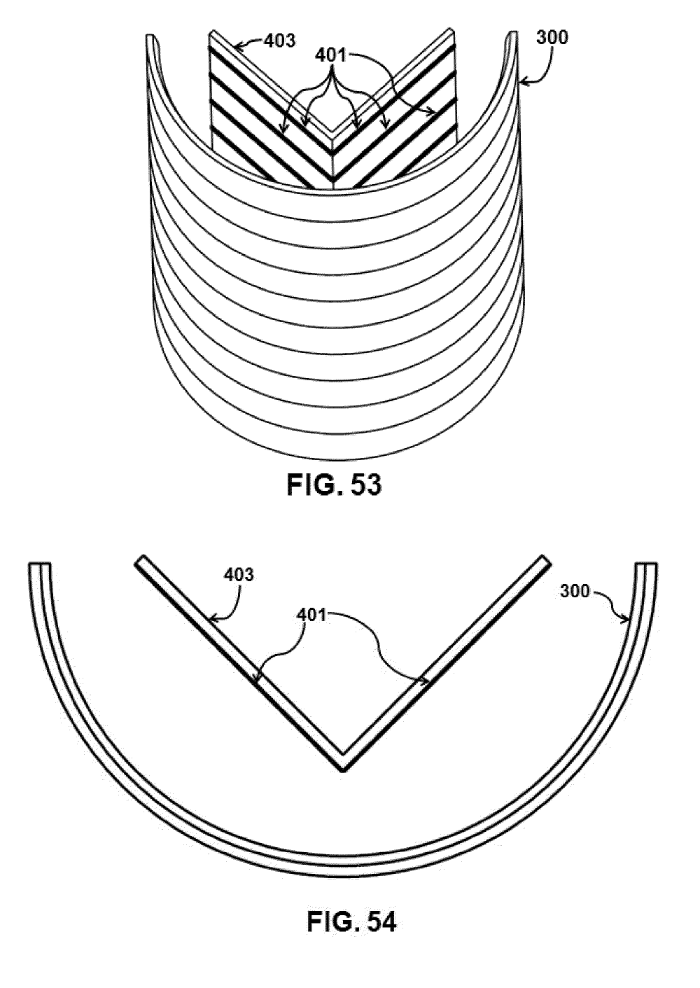

FIG. 53 shows a toroidal arc lens array with a two-facet non-planar cell card 403 and photovoltaic cells 401.

FIG. 54 is an alternate view of FIG. 53, with the line of sight parallel to the overall line focus.

The non-planar cell card embodiments described above do not limit the scope of the invention to two or three-faced non-planar cell cards. More facets may be desired depending on the parameters of the toroidal arc lens array 300 and parabolic trough segments 200.

Those skilled in the art, after having the benefit of this disclosure, will appreciate that modifications and changes may be made to the embodiments described herein, different materials may be substituted, equivalent features may be used, changes may be made in the assembly, and additional elements and steps may be added, all without departing from the scope and spirit of the invention. This disclosure has set forth certain presently preferred embodiments and examples only, and no attempt has been made to describe every variation and embodiment that is encompassed within the scope of the present invention. The scope of the invention is therefore defined by the claims appended hereto, and is not limited to the specific examples set forth in the above description.

What is claimed is:

1. An apparatus for generating electricity from solar radiation using high concentration, orthogonal focusing optics, comprising:
a cylindrically curved parabolic trough reflector having a focal ratio of F/0.5 or faster, and having a line focus;
a secondary concentrating element comprising a toroidal arc lens array, the toroidal arc lens array being positioned to intercept solar radiation reflected from the cylindrically curved parabolic trough reflector before the solar radiation comes to a focus, the toroidal arc lens array being adapted to further concentrate the solar radiation in an orthogonal direction, the toroidal arc lens array having a cross section in two-dimensions of a convex lens, and extending into a third dimension by rotation in an arc around a line parallel to a primary line focus;
a plurality of photovoltaic cells spaced along the length of the line focus, said photovoltaic cells being operative to generate electricity when illuminated with solar radiation; and,
wherein said cylindrically curved parabolic trough reflector is adapted to reflect solar radiation toward said secondary concentrating element to further concentrate said solar radiation onto said photovoltaic cells.

2. The apparatus for generating electricity from solar radiation using high concentration, orthogonal focusing optics according to claim 1, wherein:
said cylindrically curved parabolic trough reflector has a trough configuration in which different segments of the trough are slightly tilted or displaced laterally so as to form two or more parallel line foci that are slightly displaced from each other, wherein the laterally separated but parallel line foci are configured to illuminate groups of photovoltaic cells with multiple facets.

3. The apparatus for generating electricity from solar radiation using high concentration, orthogonal focusing optics according to claim 2, wherein:
the toroidal arc lens array has cross-line foci formed at regular intervals spaced along a line parallel to and close to the primary linear trough focus.

4. The apparatus for generating electricity from solar radiation using high concentration, orthogonal focusing optics according to claim 3, further comprising:
an additional refractive element is provided in the form of a rod lens positioned close to and parallel to a group of the photovoltaic cells, and being configured to image in one dimension the outline of the secondary optics onto said group of the photovoltaic cells.

5. The apparatus for generating electricity from solar radiation using high concentration, orthogonal focusing optics according to claim 4, wherein:
said photovoltaic cells are multi junction photovoltaic cells configured in parallel-connected linear arrays.

6. The apparatus for generating electricity from solar radiation using high concentration, orthogonal focusing optics according to claim 1, wherein:
the toroidal arc lens array has cross-line foci formed at regular intervals spaced along a line parallel to and close to the primary linear trough focus.

7. The apparatus for generating electricity from solar radiation using high concentration, orthogonal focusing optics according to claim 1, further comprising:
an additional refractive element is provided in the form of a rod lens positioned close to and parallel to a group of the photovoltaic cells, and being configured to image in one dimension the outline of the secondary optics onto said group of the photovoltaic cells.

8. The apparatus for generating electricity from solar radiation using high concentration, orthogonal focusing optics according to claim 1, wherein:
said photovoltaic cells are multi junction photovoltaic cells configured in parallel-connected linear arrays.

9. The apparatus for generating electricity from solar radiation using high concentration, orthogonal focusing optics according to claim 7, wherein:
said cylindrically curved parabolic trough reflector has a trough configuration in which different segments of the trough are slightly tilted or displaced laterally so as to form two or more parallel line foci that are slightly displaced from each other, wherein the laterally separated but parallel line foci are configured to illuminate groups of photovoltaic cells with multiple facets.

10. An apparatus for generating electricity from solar radiation, comprising:
a large, cylindrically-shaped reflector of fast focal ratio and having a line focus;
small photovoltaic cells configured in well-separated thin rectangular areas, regularly spaced along the length of the line focus, each rectangle oriented with its long side perpendicular to said line focus, said photovoltaic cells being operative to generate electricity when illuminated with focused solar radiation;
secondary optics near said focus comprising an array of arced lenses with toroidal surfaces, the line of rotation of said surfaces being parallel to and approximately coincident with said line focus, configured to refract in a transverse direction and further concentrate the light from said reflector onto said photovoltaic cells; and,
wherein said cylindrically shaped reflector is operative to reflect solar radiation toward said secondary optics which further concentrate said solar radiation onto said photovoltaic cells.
